(19) United States
(12) Patent Application Publication
(10) Pub. No.: US 2007/0296396 A1
(43) Pub. Date: Dec. 27, 2007

(54) Phase Difference Measurement Circuit

(75) Inventor: Hiroyuki Nakahira, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi, Osaka (JP)

(21) Appl. No.: 11/663,963

(22) PCT Filed: Sep. 21, 2005
(86) PCT No.: PCT/JP05/17415

§ 371 Date: Mar. 28, 2007

(30) Foreign Application Priority Data
Oct. 1, 2004 (JP) 2004-290611

(51) Int. Cl. G01R 25/00

(52) U.S. Cl. 324/86

(57) ABSTRACT

It is an object of the present invention to provide a phase difference measurement circuit that can accurately measure any phase difference without requiring a pulse signal having a pulse width that is sufficiently narrower than a pulse width to be measured, i.e., a very-high-speed pulse signal, which is required when measuring a phase difference of two signals with accuracy.

The phase difference measurement circuit is provided with a waveform control circuit (103) which outputs one (102) of two input signals for each predetermined period, a comparison pulse generation circuit (104) which converts a phase difference between the input signal (101) and the input signal (102) that is outputted for each predetermined period into a phase difference pulse (1042) at each predetermined timing, a periodic signal generation circuit (105) which generates a periodic signal (1051) by accumulating the phase difference pulse (1042), and a measurement circuit (106) which measures the period of the periodic signal (1051). Thereby, even when the phase difference is small, a high-speed pulse signal is dispensed with, and it is not necessary to increase the speed and precision of the circuit itself, leading to a simplified circuit construction.

### TECHNICAL FIELD

The present invention relates to a phase difference measurement circuit for measuring a phase difference between two signals.

### BACKGROUND ART

In a conventional circuit for measuring a phase difference between two signals, when measuring a phase difference, a pulse waveform having a width of the phase difference between the two signals is generated, and the width is counted with a pulse signal which is higher in speed than that for the pulse waveform (for example, refer to Japanese Published Patent No. 2783543 (Page 4, FIGS. 1 and 2)).

A phase difference judgment circuit as a conventional circuit for measuring a phase difference with a high-speed pulse signal will be described with reference to FIGS. 19 and 20.

FIG. 19 is a block diagram illustrating the phase difference judgment circuit using a high-speed pulse signal, and FIG. 20 is a diagram illustrating waveforms of signals outputted from the respective circuits.

In FIG. 19, the phase difference judgment circuit comprises waveform shaping circuits 152a and 152b for shaping the waveforms of input signals 151a and 151b, respectively, an exclusive OR circuit 153 for generating a pulse waveform S5 indicating a phase difference of the input signals, a first counter 154 for counting the pulse waveform indicating the phase difference for a predetermined period of t1, a high-speed pulse signal generator 155 for generating a high-speed pulse signal for counting the signal, a switch 156 for changing the predetermined period t1, a second counter 157 for counting the output S9 from the first counter 154 for a predetermined period t2, and an RS flip-flop 158 that outputs the detected phase difference.

Further, the outputs Q1˜Q4 of the first counter have different periods of t1 and the outputs Q4˜Q6 of the second counter have different periods of t2, and desired periods are selected for the respective outputs.

As shown in FIG. 20, the waveform shaping circuits 152a and 152b receive signals S1 and S2 that are the two input signals 151a and 151b, and generate rectangular-wave signals S3 and S4, respectively, and a pulse waveform corresponding to a phase difference between the waveform-shaped input signals S3 and S4 is generated by the exclusive OR circuit 153. The first counter 154 counts the phase difference pulse. When the phase difference pulse exceeds a predetermined count value t1, the output signal S9 that is outputted to the second counter 157 and the RS flip-flop circuit 158 becomes “1”. The second counter 157 is reset by the signal S9, and counts the high-speed pulse signal S8. When the high-speed pulse signal S8 exceeds a predetermined count value t2, the output signal S10 that is outputted to the RS flip-flop 158 becomes “1”. The RS flip-flop 158 is set by that the output signal S11 becomes “1” when the signal S9 inputted to the set terminal S becomes “1”, and it is reset by that the output signal S11 becomes “0” when the signal S10 inputted to the reset terminal R becomes “1”.

As described above, when the value obtained by counting the pulse width S5 indicating the phase difference with the high-speed pulse exceeds the predetermined count value t1, it is determined that a phase difference occurs.

### DISCLOSURE OF THE INVENTION

### Problems to be Solved by the Invention

In the conventional construction, however, when the pulse width indicating the phase difference is decreased, in order to accurately measure the pulse width, a pulse signal having a pulse width that is sufficiently narrower than the target pulse width, i.e., a very high-speed pulse signal, is required. This does not depend on the frequency of the signal to be measured, but depends on only the resolution of the required phase difference. Consequently, when it is tried to increase the resolution, a higher-speed pulse signal is required naturally.

The present invention is made to solve the above-described problems and has for its object to provide a phase difference measurement circuit that can accurately measure any phase difference without requiring a high-speed pulse signal.

### Measures to Solve the Problems

In order to solve the above-mentioned problems, according to claim 1 of the present invention, a phase difference measurement circuit for measuring a phase difference between two input signals, comprises: a waveform control circuit for outputting one of the two input signals for each predetermined period; a comparison pulse generation circuit for converting a phase difference between the one input signal that is outputted for each predetermined period from the waveform control circuit and the other input signal, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal.

Further, according to claim 2 of the present invention, a phase difference measurement circuit for measuring a phase difference between two input signals, comprises: a phase shift circuit for shifting the phase of one of the two input signals by nπ (n: natural number); a comparison pulse generation circuit for converting a phase difference between the one input signal that is shifted by nπ by the phase shift circuit and the other input signal, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal.

Further, according to claim 3 of the present invention, in the phase difference measurement circuit defined in claim 1 or 2, the periodic signal generation circuit includes: a charge pump circuit that is driven by the output of the comparison pulse generation circuit, and outputs electric charge; a capacitor in which the electric charge outputted from the charge pump circuit is stored; and a reset pulse generation unit for generating a reset pulse indicating that the voltage stored in the capacitor exceeds an arbitrary reference voltage.

Further, according to claim 4 of the present invention, in the phase difference measurement circuit defined in claim 3, the charge pump circuit controls the output charge amount according to the pulse width that is outputted from the comparison pulse generation circuit.

Further, according to claim 5 of the present invention, in the phase difference measurement circuit defined in claim 3, the measurement circuit counts the period of the reset pulse with an arbitrary clock, and converts the period of the reset pulse into a digital numeric value to output the same.

Further, according to claim 6 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a waveform control circuit for outputting the delayed signal for each predetermined period; a comparison pulse generation circuit for converting a phase difference between the input signal and the signal that is outputted for each predetermined period from the waveform control circuit, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal.

According to claim 7 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a phase shift circuit for shifting the phase of the signal that is delayed by the delay circuit, by nπ (n: natural number); a comparison pulse generation circuit for converting a phase difference between the input signal and the signal that is shifted by nπ by the phase shift circuit, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal.

According to claim 8 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount, and further delaying the phase of the delayed signal by nπ (n: natural number); a comparison pulse generation circuit for converting a phase difference between the input signal and the signal that is outputted from the delay circuit, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal.

According to claim 9 of the present invention, the phase difference measurement circuit defined in any of claims 6 to 8 further includes a delay control circuit for controlling the delay amount of the delay circuit, and the delay circuit generates two or more signals of different delay amounts from the input signal, on the basis of the control of the delay control circuit.

According to claim 10 of the present invention, in the phase difference measurement circuit defined in claim 9, the delay control circuit changes the delay amount of the delay circuit at predetermined time intervals.

According to claim 11 of the present invention, in the phase difference measurement circuit defined in claim 9, the delay control circuit performs control to monotonically increase or decrease the delay amount of the delay circuit at predetermined time intervals.

According to claim 12 of the present invention, in the phase difference measurement circuit defined in any of claims 6 to 8, the periodic signal generation circuit comprises: a charge pump circuit that is driven according to the output of the comparison pulse generation circuit, and outputs electric charge; a capacitor in which the electric charge outputted from the charge pump circuit is stored; and a reset pulse generation unit for generating a reset pulse indicating that the voltage stored in the capacitor exceeds an arbitrary reference voltage.

According to claim 13 of the present invention, in the phase difference measurement circuit defined in claim 12, the charge pump circuit controls the output charge amount according to the pulse width that is outputted from the comparison pulse generation circuit.

According to claim 14 of the present invention, in the phase difference measurement circuit defined in claim 12, the measurement circuit counts the period of the reset pulse with an arbitrary clock, and converts the period of the reset pulse into a digital numeric value to output the same.

According to claim 15 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a waveform control circuit for outputting the delayed signal for each predetermined period; a comparison pulse generation circuit for converting a phase difference between the input signal and the signal that is outputted for each predetermined period from the waveform control circuit, into a pulse width at each predetermined timing, and outputting the converted pulse width; a periodic signal generation circuit for accumulating the phase difference converted into the pulse width, and generating a periodic signal on the basis of the accumulated phase difference; a measurement circuit for measuring the period of the periodic signal; and a statistical circuit for generating statistical information of the phase difference within a predetermined period on the basis of the measurement result obtained by the measurement circuit.

According to claim 16 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a phase shift circuit for shifting the phase of the signal that is delayed by the delay circuit, by nπ (n: natural number); a comparison pulse generation circuit for converting a phase difference between the input signal and the signal that is shifted by nπ by the phase shift circuit, into a pulse width at each predetermined timing, and outputting the converted pulse width; a periodic signal generation circuit for accumulating the phase difference converted into the pulse width, and generating a periodic signal on the basis of the accumulated phase difference; a measurement circuit for measuring the period of the periodic signal; and a statistical circuit for generating statistical information of the phase difference within a predetermined period on the basis of the measurement result obtained by the measurement circuit.

According to claim 17 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount, and further delaying the phase of the delayed signal by nπ (n: natural number); a comparison pulse generation circuit for converting a phase difference between the input signal and the signal that is outputted from the delay circuit, into a pulse width at each predetermined timing, and outputting the converted pulse width; a periodic signal generation circuit for accumulating the phase difference converted into the pulse width, and generating a periodic signal on the basis of the accumulated phase difference; a measurement circuit for measuring the period of the periodic signal; and a statistical circuit for generating statistical information of the phase difference within a predetermined period on the basis of the measurement result obtained by the measurement circuit.

According to claim 18 of the present invention, in the phase difference measurement circuit defined in any of claims 15 to 17, the measurement circuit includes at least two registers for holding the measurement value, and the statistical circuit generates statistical information on the basis of the information stored in the registers.

According to claim 19 of the present invention, the phase difference measurement circuit defined in any of claims 15 to 17 further includes a delay control circuit for controlling the delay amount of the delay circuit, and the delay circuit generates two or more signals of different delay amounts from the input signal on the basis of the control of the delay control circuit.

According to claim 20 of the present invention, in the phase difference measurement circuit defined in claim 19, the delay control circuit changes the delay amount of the delay circuit at predetermined time intervals.

According to claim 21 of the present invention, in the phase difference measurement circuit defined in claim 19, the delay control circuit performs control so as to monolithically increase or decrease the delay amount of the delay circuit at predetermined time intervals.

According to claim 22 of the present invention, in the phase difference measurement circuit defined in any of claims 15 to 17, the periodic signal generation circuit comprises: a charge pump circuit that is driven according to the output of the comparison pulse generation circuit, and outputs electric charge; a capacitor in which the electric charge outputted from the charge pump circuit is stored; and a reset pulse generation unit for generating a reset pulse indicating that the voltage stored in the capacitor exceeds an arbitrary reference voltage.

According to claim 23 of the present invention, in the phase difference measurement circuit defined in claim 22, the charge pump circuit controls the output charge amount according to the pulse width that is outputted from the comparison pulse generation circuit.

According to claim 24 of the present invention, in the phase difference measurement circuit defined in claim 22, the measurement circuit counts the period of the reset pulse with an arbitrary clock, and converts the period of the reset pulse into a digital numeric value to output the same.

### EFFECTS OF THE INVENTION

According to claim 1 of the present invention, a phase difference measurement circuit for measuring a phase difference between two input signals, comprises: a waveform control circuit for outputting one of the two input signals for each predetermined period; a comparison pulse generation circuit for converting a phase difference between the one input signal that is outputted for each predetermined period from the waveform control circuit and the other input signal, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal. Therefore, even when the phase difference is small, the phase difference can be accurately measured without using a high-speed pulse, and the circuit construction can be simplified because it is not necessary to increase the speed and precision of the circuit itself.

Further, according to claim 2 of the present invention, a phase difference measurement circuit for measuring a phase difference between two input signals, comprises: a phase shift circuit for shifting the phase of one of the two input signals by nπ (n: natural number); a comparison pulse generation circuit for converting a phase difference between the one input signal that is shifted by nπ by the phase shift circuit and the other input signal, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal. Therefore, even when the phase difference is small, the phase difference can be accurately measured without using a high-speed pulse, and the circuit construction can be simplified because it is not necessary to increase the speed and precision of the circuit itself.

Further, according to claim 3 of the present invention, in the phase difference measurement circuit defined in claim 1 or 2, the periodic signal generation circuit includes: a charge pump circuit that is driven by the output of the comparison pulse generation circuit, and outputs electric charge; a capacitor in which the electric charge outputted from the charge pump circuit is stored; and a reset pulse generation unit for generating a reset pulse indicating that the voltage stored in the capacitor exceeds an arbitrary reference voltage. Therefore, even when the phase difference is minute, since the phase difference is converted into an electric charge amount and stored, the phase difference can be accurately measured without requiring a high-speed pulse signal.

Further, according to claim 4 of the present invention, in the phase difference measurement circuit defined in claim 3, the charge pump circuit controls the output charge amount according to the pulse width that is outputted from the comparison pulse generation circuit. Therefore, even when the phase difference is minute, an electric charge amount corresponding to the phase difference can be outputted, thereby enabling accurate measurement of the phase difference without requiring a high-speed pulse signal.

Further, according to claim 5 of the present invention, in the phase difference measurement circuit defined in claim 3, the measurement circuit counts the period of the reset pulse with an arbitrary clock, and converts the period of the reset pulse into a digital numeric value to output the same. Therefore, a minute phase difference between the two input signals as analog signals can be obtained as a digital numeric value, thereby enabling accurate measurement of the phase difference without requiring a high-speed pulse signal.

Further, according to claim 6 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a waveform control circuit for outputting the delayed signal for each predetermined period; a comparison pulse generation circuit for converting a phase difference between the input signal and the signal that is outputted for each predetermined period from the waveform control circuit, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal. Therefore, it is possible to confirm whether the set delay amount is normally delayed or not by detecting the phase difference that is generated by the delay circuit 303, thereby enabling judgment as to whether the delay circuit that can set a predetermined delay amount is normally operated or not.

According to claim 7 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a phase shift circuit for shifting the phase of the signal that is delayed by the delay circuit, by nπ (n: natural number); a comparison pulse generation circuit for converting a phase difference between the input signal and the signal that is shifted by nπ by the phase shift circuit, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal. Therefore, it is possible to confirm whether the set delay amount is normally delayed or not by detecting the phase difference that is generated by the delay circuit 303, thereby enabling judgment as to whether the delay circuit that can set a predetermined delay amount is normally operated or not.

According to claim 8 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount, and further delaying the phase of the delayed signal by nπ (n: natural number); a comparison pulse generation circuit for converting a phase difference between the input signal and the signal that is outputted from the delay circuit, into a pulse width at each predetermined timing, and outputting the converted pulse width; a periodic signal generation circuit for accumulating the phase difference converted into the pulse width, and generating a periodic signal on the basis of the accumulated phase difference; and a measurement circuit for measuring the period of the periodic signal. Therefore, it is possible to confirm whether the set delay amount is normally delayed or not by detecting the phase difference that is generated by the delay circuit 303, thereby enabling judgment as to whether the delay circuit that can set a predetermined delay amount is normally operated or not.

According to claim 9 of the present invention, the phase difference measurement circuit defined in any of claims 6 to 8 further includes a delay control circuit for controlling the delay amount of the delay circuit, and the delay circuit generates two or more signals of different delay amounts from the input signal, on the basis of the control of the delay control circuit. Therefore, it is possible to confirm whether the set two or more delay amounts are normally delayed or not, thereby enabling judgment as to whether the delay circuit that can set the two or more different delay amounts is normally operated or not.

According to claim 10 of the present invention, in the phase difference measurement circuit defined in claim 9, the delay control circuit changes the delay amount of the delay circuit at predetermined time intervals. Therefore, it is possible to confirm, for each time interval, whether the set two or more delay amounts are normally delayed or not, thereby enabling judgment as to whether the delay circuit that can set the two or more different delay amounts is normally operated or not.

According to claim 11 of the present invention, in the phase difference measurement circuit defined in claim 9, the delay control circuit performs control to monotonically increase or decrease the delay amount of the delay circuit at predetermined time intervals. Therefore, it is possible to confirm, for each time interval, whether the set two or more delay amounts are stepwisely and normally delayed or not, thereby enabling judgment as to whether the delay circuit that can set two or more different delay amounts is normally operated or not.

According to claim 12 of the present invention, in the phase difference measurement circuit defined in any of claims 6 to 8, the periodic signal generation circuit comprises: a charge pump circuit that is driven according to the output of the comparison pulse generation circuit, and outputs electric charge; a capacitor in which the electric charge outputted from the charge pump circuit is stored; and a reset pulse generation unit for generating a reset pulse indicating that the voltage stored in the capacitor exceeds an arbitrary reference voltage. Therefore, even when a phase difference is generated by a minute delay amount, since the phase difference is converted into an electric charge amount and stored, the phase difference can be accurately measured without requiring a high-speed pulse signal.

According to claim 13 of the present invention, in the phase difference measurement circuit defined in claim 12, the charge pump circuit controls the output charge amount according to the pulse width that is outputted from the comparison pulse generation circuit. Therefore, even when a phase difference is generated by a minute delay amount, an electric charge amount corresponding to the phase difference can be outputted, whereby the phase difference can be accurately measured without requiring a high-speed pulse signal.

According to claim 14 of the present invention, in the phase difference measurement circuit defined in claim 12, the measurement circuit counts the period of the reset pulse with an arbitrary clock, and converts the period of the reset pulse into a digital numeric value to output the same. Therefore, a phase difference that is generated by a minute delay amount can be obtained as a digital numeric value, thereby enabling accurate measurement of the phase difference without requiring a high-speed pulse signal.

According to claim 15 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a waveform control circuit for outputting the delayed signal for each predetermined period; a comparison pulse generation circuit for converting a phase difference between the input signal and the signal that is outputted for each predetermined period from the waveform control circuit, into a pulse width at each predetermined timing, and outputting the converted pulse width; a periodic signal generation circuit for accumulating the phase difference converted into the pulse width, and generating a periodic signal on the basis of the accumulated phase difference; a measurement circuit for measuring the period of the periodic signal; and a statistical circuit for generating statistical information of the phase difference within a predetermined period on the basis of the measurement result obtained by the measurement circuit. Therefore, it is possible to confirm whether the set delay amount is normally delayed or not by detecting the phase difference generated by the delay circuit, thereby automatically performing judgment as to whether the delay circuit that can set a predetermined delay amount is normally operated or not.

According to claim 16 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount; a phase shift circuit for shifting the phase of the signal that is delayed by the delay circuit, by nπ (n: natural number); a comparison pulse generation circuit for converting a phase difference between the input signal and the signal that is shifted by nπ by the phase shift circuit, into a pulse width at each predetermined timing, and outputting the converted pulse width; a periodic signal generation circuit for accumulating the phase difference converted into the pulse width, and generating a periodic signal on the basis of the accumulated phase difference; a measurement circuit for measuring the period of the periodic signal; and a statistical circuit for generating statistical information of the phase difference within a predetermined period on the basis of the measurement result obtained by the measurement circuit. Therefore, it is possible to confirm whether the set delay amount is normally delayed or not by detecting the phase difference generated by the delay circuit, thereby automatically performing judgment as to whether the delay circuit that can set a predetermined delay amount is normally operated or not.

According to claim 17 of the present invention, a phase difference measurement circuit for measuring a phase difference between an input signal having a predetermined period and a signal that is obtained by delaying the input signal by a predetermined delay amount, comprises: a delay circuit for delaying the input signal by a predetermined delay amount, and further delaying the phase of the delayed signal by nπ (n: natural number); a comparison pulse generation circuit for converting a phase difference between the input signal and the signal that is outputted from the delay circuit, into a pulse width at each predetermined timing, and outputting the converted pulse width; a periodic signal generation circuit for accumulating the phase difference converted into the pulse width, and generating a periodic signal on the basis of the accumulated phase difference; a measurement circuit for measuring the period of the periodic signal; and a statistical circuit for generating statistical information of the phase difference within a predetermined period on the basis of the measurement result obtained by the measurement circuit. Therefore, it is possible to confirm whether the set delay amount is normally delayed or not by detecting the phase difference generated by the delay circuit, thereby automatically performing judgment as to whether the delay circuit that can set a predetermined delay amount is normally operated or not.

According to claim 18 of the present invention, in the phase difference measurement circuit defined in any of claims 15 to 17, the measurement circuit includes at least two registers for holding the measurement value, and the statistical circuit generates statistical information on the basis of the information stored in the registers. Therefore, it is possible to confirm whether the set delay amount is normally delayed or not by detecting the phase differences that are held in the respective registers, thereby automatically performing judgment as to whether the delay circuit that can set a predetermined delay amount is normally operated or not.

According to claim 19 of the present invention, the phase difference measurement circuit defined in any of claims 15 to 17 further includes a delay control circuit for controlling the delay amount of the delay circuit, and the delay circuit generates two or more signals of different delay amounts from the input signal on the basis of the control of the delay control circuit. Therefore, it is possible to confirm whether the set two or more delay amounts are normally delayed or not, thereby automatically performing judgment as to whether the delay circuit that can set two or more different delay amounts is normally operated or not.

According to claim 20 of the present invention, in the phase difference measurement circuit defined in claim 19, the delay control circuit changes the delay amount of the delay circuit at predetermined time intervals. Therefore, it is possible to confirm, for each time interval, whether the set two or more delay amounts are normally delayed or not, thereby automatically performing judgment as to whether the delay circuit that can set two or more different delay amounts is normally operated or not.

According to claim 21 of the present invention, in the phase difference measurement circuit defined in claim 19, the delay control circuit performs control so as to monolithically increase or decrease the delay amount of the delay circuit at predetermined time intervals. Therefore, it is possible to confirm, for each time interval, whether the set two or more delay amounts are stepwisely and normally delayed or not, thereby automatically performing judgment as to whether the delay circuit that can set two or more different delay amounts is normally operated or not.

According to claim 22 of the present invention, in the phase difference measurement circuit defined in any of claims 15 to 17, the periodic signal generation circuit comprises: a charge pump circuit that is driven according to the output of the comparison pulse generation circuit, and outputs electric charge; a capacitor in which the electric charge outputted from the charge pump circuit is stored; and a reset pulse generation unit for generating a reset pulse indicating that the voltage stored in the capacitor exceeds an arbitrary reference voltage. Therefore, even when a phase difference is generated by a minute delay amount, since the phase difference is converted into an electric charge amount and stored, the phase difference can be accurately measured without requiring a high-speed pulse signal.

According to claim 23 of the present invention, in the phase difference measurement circuit defined in claim 22, the charge pump circuit controls the output charge amount according to the pulse width that is outputted from the comparison pulse generation circuit. Therefore, even when a phase difference is generated by a minute delay amount, an electric charge amount corresponding to the phase difference can be outputted, whereby the phase difference can be accurately measured without requiring a high-speed pulse signal.

According to claim 24 of the present invention, in the phase difference measurement circuit defined in claim 22, the measurement circuit counts the period of the reset pulse with an arbitrary clock, and converts the period of the reset pulse into a digital numeric value to output the same. Therefore, a phase difference that is generated by a minute delay amount can be obtained as a digital numeric value, thereby enabling accurate measurement of the phase difference without requiring a high-speed pulse signal.

### BRIEF DESCRIPTION OF THE DRAWINGS

FIG. 1 is a block diagram illustrating the construction of a phase difference measurement circuit according to a first embodiment of the present invention.

FIG. 2 is a diagram illustrating an example of a comparison pulse generation circuit of the phase difference measurement circuit according to the first embodiment, and the relationship between input and output.

FIG. 3 is a block diagram illustrating the construction of a periodic signal generation circuit of the phase difference measurement circuit according to the first embodiment of the present invention.

FIG. 4 is a diagram illustrating the specific construction of the periodic signal generation circuit of the phase difference measurement circuit according to the first embodiment of the present invention.

FIG. 5 is a diagram illustrating equivalent conversion and accumulation of phase difference in the phase difference measurement circuit according to the first embodiment of the present invention.

FIG. 6 is a diagram illustrating the relationship between a phase difference and a periodic signal in the phase difference measurement circuit according to the first embodiment of the present invention.

FIG. 7 is a diagram illustrating accumulation of phase difference in the phase difference measurement circuit according to the first embodiment of the present invention.

FIG. 8 is a block diagram illustrating the construction of a phase difference measurement circuit according to a second embodiment of the present invention.

FIG. 9 is a diagram illustrating an example of a comparison pulse generation circuit of the phase difference measurement circuit according to the second embodiment of the present invention, and the relationship between input and output.

FIG. 10 is a block diagram illustrating the construction of a phase difference measurement circuit according to a third embodiment of the present invention.

FIG. 11 is a diagram illustrating an example of a delay circuit of the phase difference measurement circuit according to the third embodiment of the present invention.

FIG. 12 is a block diagram illustrating the construction of a phase difference measurement circuit according to a fourth embodiment of the present invention.

FIG. 13 is a block diagram illustrating the construction of a phase difference measurement circuit according to a fifth embodiment of the present invention.

FIG. 14 is a block diagram illustrating the construction of a phase difference measurement circuit according to a sixth embodiment of the present invention.

FIG. 15 is a diagram illustrating an example of a measurement circuit of the phase difference measurement circuit according to the sixth embodiment of the present invention.

FIG. 16 is a diagram illustrating the relationship between input and output of the measurement circuit of the phase difference measurement circuit according to the sixth embodiment of the present invention.

FIG. 17 is a block diagram illustrating the construction of a phase difference measurement circuit according to a seventh embodiment of the present invention.

FIG. 18 is a block diagram illustrating the construction of a phase difference measurement circuit according to an eighth embodiment of the present invention.

FIG. 19 is a diagram illustrating the construction of a phase difference judgment circuit that measures a phase difference using a high-speed pulse.

FIG. 20 is a diagram illustrating waveforms of signals outputted from the respective circuits in the phase difference judgement circuit shown in FIG. 19.

### DESCRIPTION OF REFERENCE NUMERALS

10,20,30,40,50,60,70,80 . . . phase difference measurement circuit
101,102,301 . . . input signal
103 . . . waveform control circuit
104 . . . comparison pulse generation circuit
105 . . . periodic signal generation circuit
106,306 . . . measurement circuit
108,208,308,408 . . . output of phase difference measurement circuit
203 . . . phase shift circuit
303,503,803 . . . delay circuit
310 . . . delay control circuit
407 . . . statistical circuit
1031 . . . output signal of waveform control circuit
1041 . . . output obtained by enable signal
1042 . . . phase difference pulse
1051 . . . periodic signal
1052 . . . charge pump circuit
1053 . . . triangle wave generation circuit
1054 . . . comparator
2031 . . . output signal of phase shift circuit
3031 . . . output signal of delay circuit
3038 . . . multiplexer
3061 . . . counter
3062 . . . register A
3063 . . . register B
3064 . . . comparator
3100a . . . clock
3100b . . . reset signal
4071 . . . OR gate
4072 . . . D flip-flop
5031 . . . output signal of delay circuit 503
8031 . . . output signal of delay circuit 803
10521 . . . current source
10522,10532 . . . switch
10531 . . . capacitor
10533 . . . node
30300˜30307 . . . buffer
151a,151b . . . input signal
152a,152b . . . waveform shaping circuit
153 . . . exclusive OR circuit
154 . . . first counter
155 . . . high-speed pulse signal generator
156 . . . switch
157 . . . second counter
158 . . . RS flip-flop

### BEST MODE TO EXECUTE THE INVENTION

Hereinafter, preferred embodiments for executing the present invention will be described with reference to the drawings.

### Embodiment 1

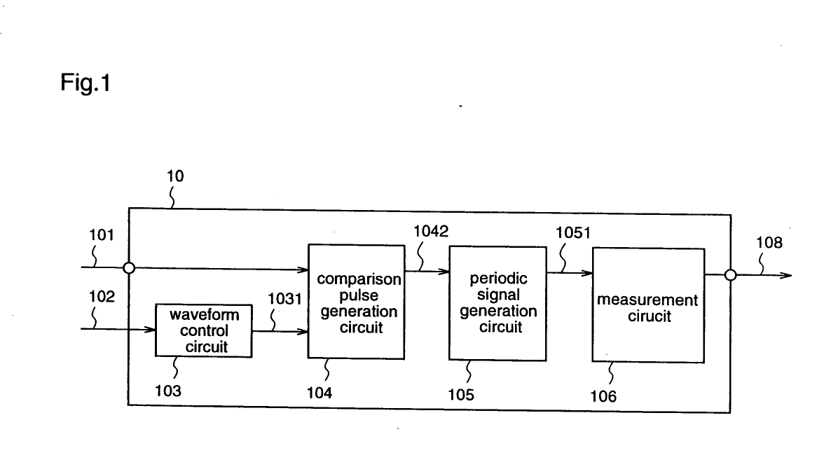

FIG. 1 is a block diagram illustrating the construction of a phase difference measurement circuit 10 according to a first embodiment of the present invention.

In FIG. 1, the phase difference measurement circuit 10 comprises a waveform control circuit 103 which outputs an input signal 102 that is one of two input signals, for each predetermined period, a comparison pulse generation circuit 104 which converts a phase difference between the input signal 1031 outputted from the waveform control circuit 103 and an input signal 101 that is the other input signal, into a pulse width for each predetermined timing, and outputs the converted pulse width as a phase difference pulse 1042, a periodic signal generation circuit 105 which accumulates the phase difference pulse 1042 obtained in the comparison pulse generation circuit 104, and generates a periodic signal 1051 on the basis of the accumulated phase difference, and a measurement circuit 106 which measures the periodic signal 1051 outputted from the periodic signal generation circuit 105.

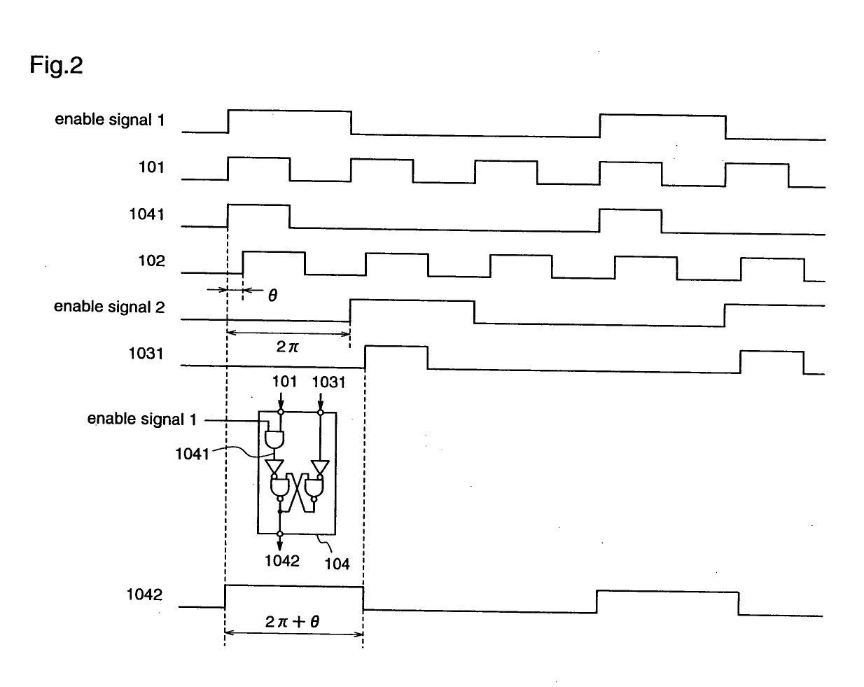

Next, a description will be given of the operation of generating a phase difference pulse 1042 in the phase difference measurement circuit 10 constituted as described above, with reference to FIG. 2.

The waveform control circuit 103 outputs the input signal 102 for each predetermined period. For example, as shown in FIG. 2, a period during which an enable signal 2 is “Hi” is an output period of the input signal 102, and the input signal 102 is outputted for every predetermined period. When the enable signal 2 as shown in FIG. 2 is adopted, the phase of the input signal 102 is delayed by just 2π relative to the input signal 101.

The comparison pulse generation circuit 104 outputs a phase difference pulse 104 having a pulse width corresponding to a phase difference between rising edges of the two signals, i.e., the input signal 101 and the output 1031 of the waveform control circuit 103. When an RS latch circuit as shown in FIG. 2 is constituted as an example of the comparison pulse generation circuit 104, a phase difference pulse 1042 can be generated. Thus, the RS latch circuit generates a phase difference pulse 1042 between the output 1031 of the waveform control circuit 103 and the signal 1041 that is obtained by performing waveform control for the input signal 101 with the enable signal 1 which has the same period and different timing as/from those of the enable signal 2, whereby the two input signals 101 and 102 having a phase difference θ are converted into two signals having a phase difference 2π+θ, and a phase difference pulse 1042 having the phase difference 2π+θ as a pulse width is generated. When the input signals are periodic signals, θ and (2π+θ) are equivalent to each other. Then, the phase difference pulse 1042 is inputted to the periodic signal generation circuit 105.

While in this first embodiment the RS latch circuit is used as the comparison pulse generation circuit 104, the comparison pulse generation circuit 104 is not restricted thereto, and any circuit may be used so long as it can generate a phase difference pulse 1042 that is obtained by adding 2π to the phase difference between the input signals 101 and 102. That is, while in this first embodiment waveform control for the input signal 101 is performed in the RS latch circuit, waveform control for the input signal 101 may be performed in the stage before the RS latch circuit, and further, waveform control for the input signal 102 that has been performed by the waveform control circuit 103 may be performed in the RS latch circuit.

The enable signal 2 may be outputted at an arbitrary period, and then the enable signal 1 may have the same period as and different timing from those of the enable signal 2.

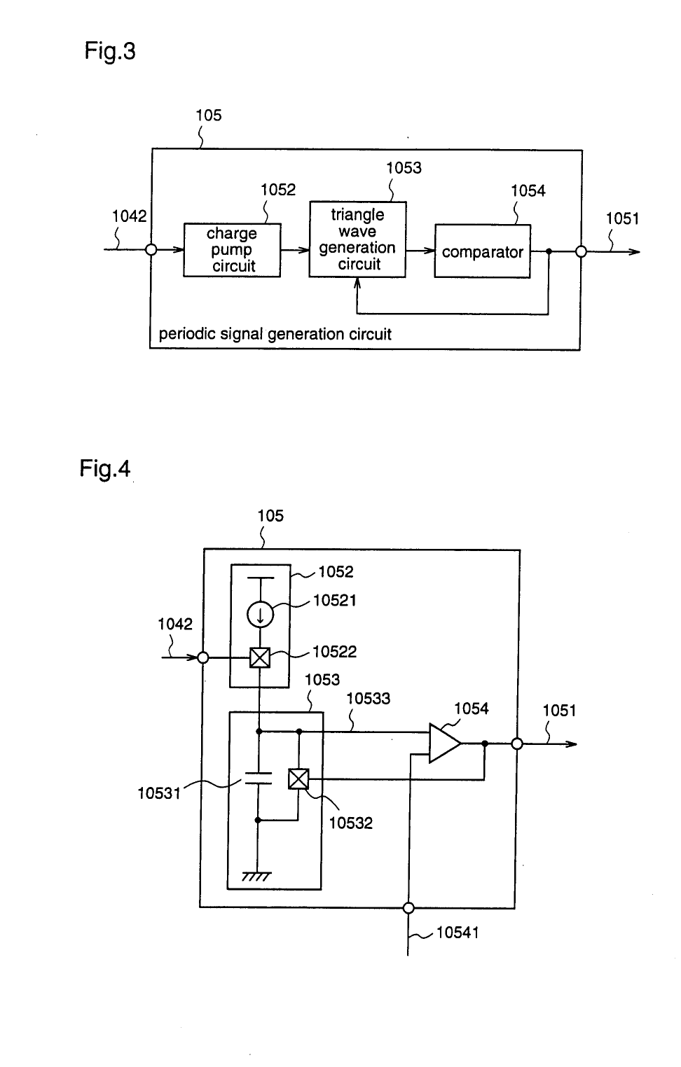

FIG. 3 is a block diagram illustrating the periodic signal generation circuit 105.

In FIG. 3, the periodic signal generation circuit 105 comprises a charge pump circuit 1052 which is driven according to the phase difference pulse 1042 outputted from the comparison pulse generation circuit 104, and outputs electric change, a triangle wave generation circuit 1053 which accumulates a predetermined amount of the electric charge outputted from the charge pump circuit 1052 to generate a triangle wave, and a comparator 1054 which generates a periodic signal using the triangle wave outputted from the triangle wave generation circuit 1053.

FIG. 4 is a diagram illustrating the periodic signal generation circuit 105 shown in FIG. 3 in more detail.

In FIG. 4, the charge pump circuit 1052 has a current source 10521 which outputs electric charge, and a switch 10522 which is controlled by the phase difference pulse 1042, and the electric charge supplied from the current source 10521 is outputted to the triangle wave generation circuit 1053 through the switch 10522. The triangle wave generation circuit 1053 includes a capacitor 10531 in which the electric charge is stored, and a switch 10532 for resetting the capacitor, and the electric charge outputted from the charge pump circuit 1052 is successively stored in the capacitor 10531. The comparator 1054 receives the output from the capacitor 10531 and an arbitrary reference voltage 10541, and serves as a reset pulse generation unit for generating a reset pulse indicating that the voltage charged in the capacitor 10531 exceeds the arbitrary reference voltage 10541 to output the generated reset pulse as a periodic signal. Further, the reset pulse is also outputted to the switch 10532 of the triangle wave generation circuit 1053, and the capacitor 10531 is refreshed by the output of the reset pulse.

Hereinafter, the operation of the periodic signal generation circuit 105 of the phase difference measurement circuit 10 according to the first embodiment will be described with reference to FIG. 4.

The charge pump circuit 1052 outputs the electric charge supplied from the current source 10521 to the triangle wave generation circuit 1053 through the switch 10522. The triangle wave generation circuit 1053 successively stores the electric charge in the capacitor 10531. Through the above-mentioned procedure, the amount of time that is given by the phase difference pulse 1042, that is, the phase difference between the input signals 101 and 102 of the phase difference measurement circuit, is converted into a current pulse, and thereafter, converted into an electric charge amount.

The output of the comparator 1054 changes when the electric charge stored in the capacitor 10531 exceeds the reference voltage 10541 that is a charge amount as a predetermined amount of phase difference. That is, a reset pulse is generated at this time. Then, the capacitor 10531 is refreshed by the output of the reset pulse from the comparator 1054.

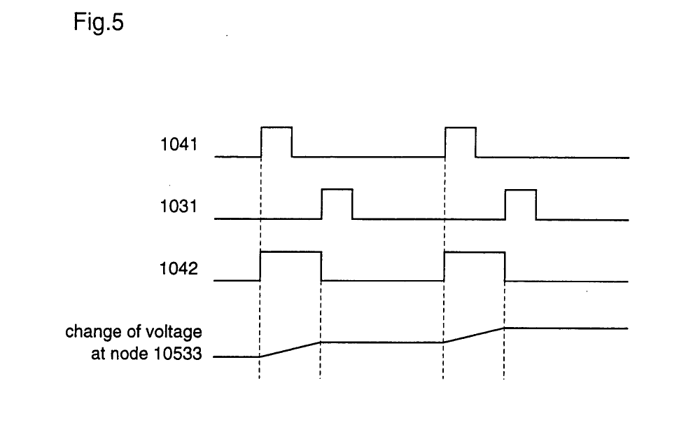

FIG. 5 shows the output of the capacitor 10531, that is, the relationship between the voltage at the node 10533 and the phase difference pulse 1042. As described above, the charge pump circuit 1052 and the triangle wave generation circuit 1053 serve as a time-to-voltage conversion circuit. Since the pulse width of the phase difference pulse 1042 corresponds to a time for charging the capacitor 10531, the voltage of the node 10533 rises in the period when the phase difference pulse 1042 is “Hi” as shown in FIG. 5. That is, in the charge pump circuit 1052, the output charge amount is controlled according to the pulse width of the phase difference pulse 1042.

The output of the capacitor 10531, i.e., the node 10533, has a voltage that is determined by the capacitance value and the accumulation of the phase difference between the input signals 101 and 102. Further, when the node 10533 is a first input to the comparator 1054 and the arbitrary reference voltage 10541 is a second input to the comparator 1054, the output of the comparator 1054 changes at the timing when the node 10533 exceeds the reference voltage 10541, whereby a reset pulse is outputted. Further, when the output 1051 of the comparator 1054, i.e., the reset pulse, is inputted to the switch 10532, the triangle wave generation circuit 1053 discharges the stored electric charge, whereby the voltage of the node 10533 becomes 0. That is, since the voltage of the node 10533 indicates the cumulative amount of the phase difference between the two input signals 101 and 102 as described above, when it exceeds the reference voltage 10541, the output of the comparator 1054 changes on the assumption that the predetermined amount of phase difference has been accumulated, whereby the switch 10532 is turned on by the reset pulse that is outputted from the comparator 1054, and the capacitor 10531 is refreshed. At the same time as the capacitor 10531 is refreshed, the output of the comparator 1054 again changes, and next accumulation is started from this timing.

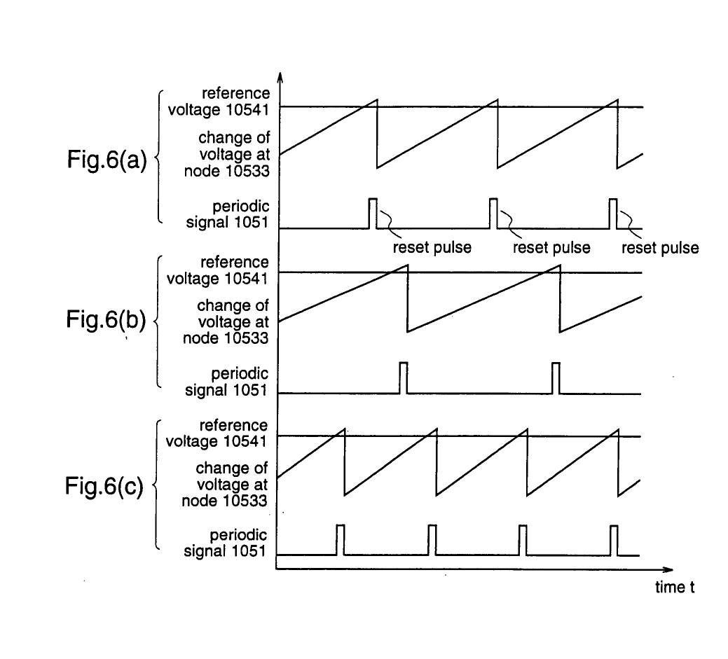

The resultant output 1051 from the comparator 1054 is a periodic signal. FIG. 6 is a diagram illustrating the relationship between the periodic signal 1051 and the phase difference between the two signals 101 and 102.

As shown in FIG. 6(a), the voltage of the node 10533 rises due to the effect that the phase difference pulse between the input signals 101 and 102 is stored as electric charge, as described above. When the voltage of the node exceeds the reference voltage 10541, the output of the comparator 1054 changes, that is, a reset pulse is outputted, whereby the capacitor 10531 is refreshed and the voltage of the node 10533 becomes 0. By repeating this operation, a periodic signal 1051 is generated.

Then, the period of the periodic signal 1051 is measured by the measurement circuit 106. As an example of the measurement circuit, a counter may be adopted. The clock of the counter may have an arbitrary frequency, and it may have the same frequency as that of the input signal. Thereby, the phase difference between the two input signals as analog signals can be obtained as a digital numeric value, and this value is the measurement result of the phase difference measurement circuit 10. The clock of the counter is desired to be a clock having a frequency which can express that the count value of the smallest phase difference of the calculated original phase difference is 1 digit or more, and the precision is improved with an increase in the number of digits.

FIG. 6(b) shows the case where the original phase difference θ is small. In this case, since the pulse width of the phase difference pulse 1042 is narrow, the voltage rising value of the node 10533 for each pulse is small. Therefore, there are required many times of comparison between the input signals 101 and 102 until the charged voltage 10533 of the capacitor 10531 becomes equal to the reference voltage 10541, that is, the time required until the output of the comparator 1054 changes is increased. Accordingly, the period of the periodic signal 1051 is increased, and the digital numeric value outputted from the measurement circuit 106 shows a large value.

On the other hand, FIG. 6(c) shows the case where the phase difference is large. In this case, since the pulse width of the phase difference pulse 1042 is large, the voltage rising value of the node 10533 for each pulse is large, and the number of times of comparison between the input signals 101 and 102, which are required until the charged voltage 10533 of the capacitor 10531 becomes equal to the reference voltage 10541, is relatively small. That is, the time required until the output of the comparator 1054 changes is reduced. Accordingly, the period of the periodic signal 1051 is reduced, and the digital numeric value outputted from the measurement circuit 106 shows a small value.

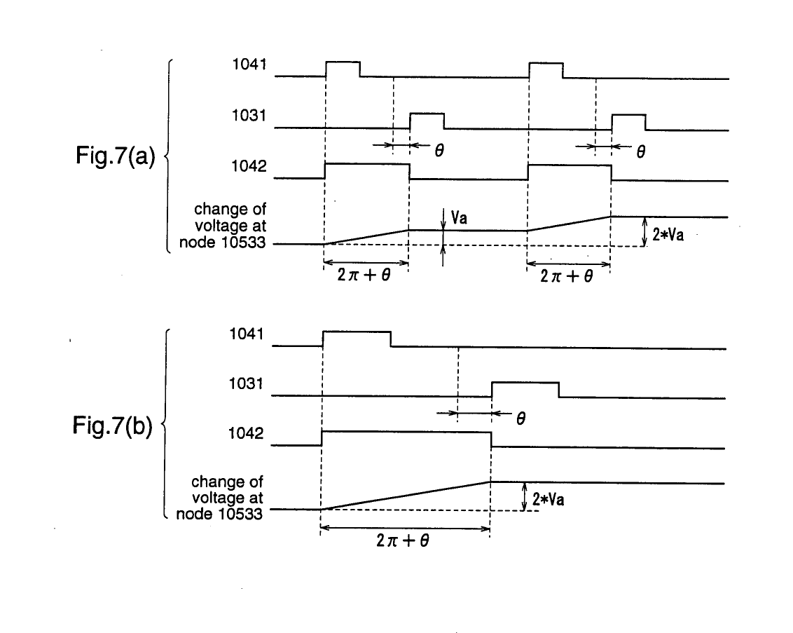

FIG. 7 shows the relationship between the frequencies of the two input signals and the phase difference between them. As shown in FIG. 7(a), when the phase difference between the two input signals 101 and 102 is θ, the pulse width of the phase difference pulse 1042 is 2π+θ. At this time, assuming that the voltage of the node 10533 rises by Va with single charging, the voltage rise is 2×Va with two times of charging.

On the other hand, FIG. 7(b) shows the state where the frequencies of the two input signals are halved, i.e., the periods thereof are doubled. In this case, even when the phase difference is 2π+θ, the voltage undesirably rises by 2×Va with single charging. So, at this time, the current source 10521 for charging the capacitor 10531 is halved, whereby the voltage rise becomes Va even with single charging. That is, the precision of measurement can be kept by adaptively changing the size of the current source 10521 according to the frequencies of the input signals.

As described above, the phase difference between the two input signals 101 and 102 is converted into the period of the periodic signal 1051, and the phase difference can be obtained as a digital numeric value by measuring this period. At this time, since conversion of the phase difference, which is equivalent to addition of 2π to the phase difference, is carried out in the waveform control circuit 103, even when the phase difference is minute one that cannot generate a pulse width indicating the correct phase difference θ, the phase difference can be precisely measured. The phase difference of 2π can be obtained when the phase difference between the two signals is 0, and it can be easily measured by, for example, giving the same signal to the input signals 101 and 102. Further, since 2π corresponds to one period of the signal, if the period is found, the time lag between the two input signals can also be calculated by using the result of measurement by the phase difference measurement circuit 10.

The phase difference measurement circuit according to the first embodiment of the present invention is provided with the waveform control circuit 103 which outputs the input signal 102 for each predetermined period, the comparison pulse generation circuit 104 which outputs a phase difference between the input signal 101 and the output 1031 from the waveform control circuit as a pulse width at each predetermined timing, the periodic signal generation circuit 105 which converts the phase difference pulse outputted from the comparison pulse generation circuit 104 into an amount of electric charge, stores the obtained electric charge amount, and generates a periodic signal on the basis of the stored electric charge amount, and the measurement circuit which measures the period of the periodic signal that is generated by the periodic signal generation circuit, and outputs the phase difference between the two input signals as analog signals, as a digital numeric value. Since the phase difference pulse that is obtained by adding 2π to the phase difference between the input signals 101 and 102 is accumulated as electric charge, even when the phase difference between the two input signals is a minute phase difference that cannot generate a pulse width indicating the correct phase difference θ, the phase difference can be precisely measured without requiring a high-speed pulse signal, and it is not necessary to increase the speed and precision of the circuit itself, resulting in a simplified circuit construction.

While in the phase difference measurement circuit according to the first embodiment the waveform control circuit 103 generates an output signal so that the phase difference pulse indicating the phase difference between the two input signals is obtained by adding 2π to the original phase difference, the waveform control circuit 103 may generate an output signal so that the phase difference pulse is obtained by adding nπ (n: natural number) to the original phase difference.

### Embodiment 2

A phase difference measurement circuit according to a second embodiment of the present invention is provided with a phase shift circuit for shifting an input signal by a predetermined phase, in place of the waveform control circuit in the first embodiment.

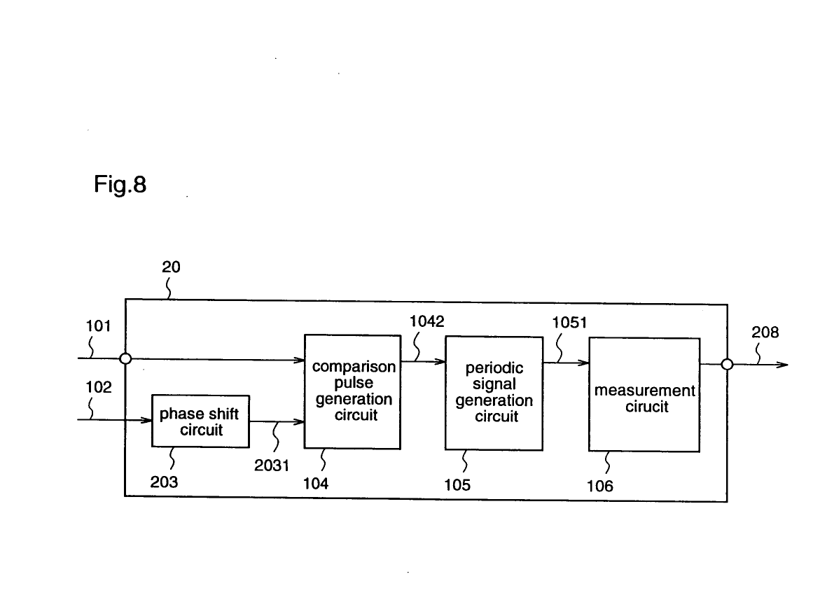

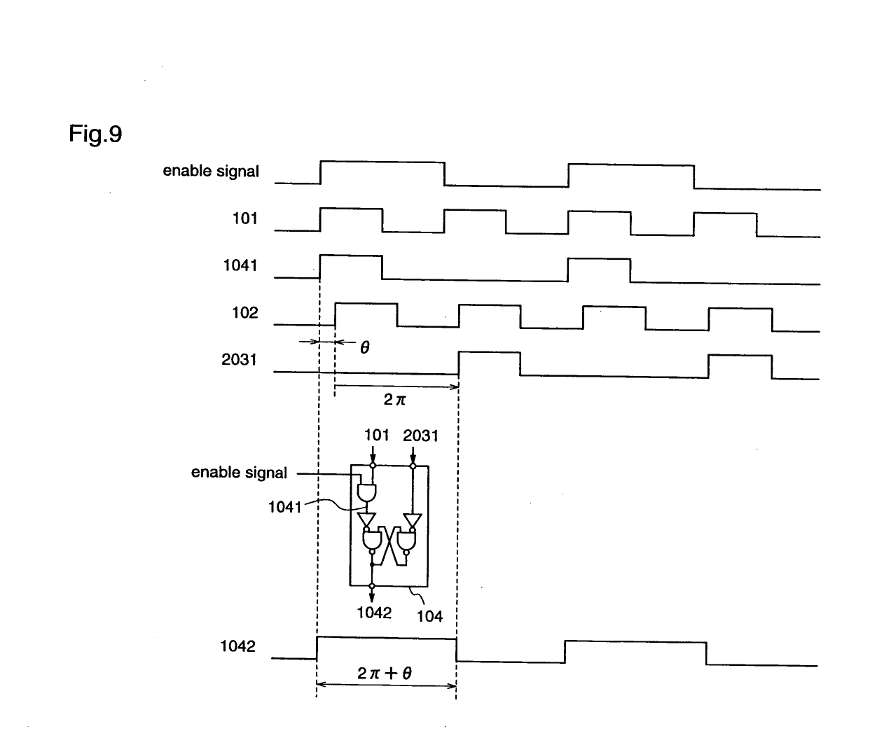

The phase difference measurement circuit relating to the second embodiment will be described with reference to FIGS. 8 and 9. The same constituents as those described for the first embodiment are not repeatedly described, and only the constituents different from those of the first embodiment will be described.

FIG. 8 is a diagram illustrating the construction of the phase difference measurement circuit according to the second embodiment of the present invention, and FIG. 9 is a diagram illustrating an example of a comparison pulse generation circuit of the phase difference measurement circuit according to the second embodiment, and the relationship between the input and the output.

The phase difference measurement circuit 20 according to the second embodiment is, as shown in FIG. 8, provided with a phase shift circuit 203 which shifts an input signal 102 by a predetermined phase and outputs the same, in place of the waveform control circuit 103 in the first embodiment. At this time, the phase shift circuit 203 shifts the input signal 102 by a predetermined phase, and outputs the same. For example, as shown in FIG. 9, the phase shift circuit 203 shifts the input signal 102 so as to obtain an output signal 2031 having a phase in which each pulse is delayed by 2π. The comparison pulse generation circuit 104 outputs a phase difference pulse 1042 having a pulse width corresponding to a phase difference between the rising edges of the two signals, i.e., the input signal 101 and the output 2031 of the phase shift circuit. As an example of the comparison pulse generation circuit 104 that performs the above-mentioned operation, an RS latch circuit identical to that shown in FIG. 2 can be adopted, and thereby a phase difference pulse 1042 can be generated. Thus, a phase difference pulse 1042 between a signal 1041 that is obtained by waveform-controlling the input signal 101 with an enable signal and the output 2031 that is phase-shifted by the phase shift circuit 203 is generated in the RS latch circuit, whereby the two input signals 101 and 102 having a phase difference θ are converted into two signal having a phase difference 2π+θ, and a phase difference pulse 1042 having the phase difference 2π+θ as a pulse width is generated. When the input signals are periodic signals, θ and (2π+θ) are equivalent to each other. That is, when the shift amount of the phase shift circuit 203 is 2π and the enable signal of the waveform control circuit 103 shown in FIG. 1 is in the state shown in FIG. 2, the waveform control circuit 103 and the phase shift circuit 203 are functionally equivalent circuits. Accordingly, the operation subsequent to the comparison pulse generation circuit 104 is identical to that described for the first embodiment.

While the RS latch circuit is used as the comparison pulse generation circuit 104 in the phase difference measurement circuit 20 according to the second embodiment, the comparison pulse generation circuit 104 is not restricted thereto, and any circuit may be used so long as it can generate a phase difference pulse 1042 by adding 2π to the phase difference between the input signals 101 and 102.

Further, the waveform control for the input signal 101 may be performed in the stage before the RS latch circuit, as in the first embodiment.

As described above, the phase difference measurement circuit according to the second embodiment of the present invention is provided with the phase shift circuit 203 which shifts the input signal 102 by a predetermined phase and outputs the same, the comparison pulse generation circuit 204 which outputs a phase difference between the input signal 101 and the output 2031 from the phase shift circuit 203 as a pulse width at each predetermined timing, the periodic signal generation circuit 105 which converts the phase difference pulse outputted from the comparison pulse generation circuit 104 into an amount of electric charge, stores the obtained electric charge amount, and generates a periodic signal on the basis of the stored electric charge amount, and the measurement circuit which measures the period of the periodic signal that is generated in the periodic signal generation circuit, and outputs the phase difference between the two input signals as analog signals, as a digital numeric value. Since the phase difference pulse that is obtained by adding 2π to the phase difference between the input signals 101 and 102 is accumulated as electric charge, even when the phase difference between the two input signals is a minute phase difference that cannot generate a pulse width indicating the correct phase difference θ, the phase difference can be precisely measured without requiring a high-speed pulse signal, and it is not necessary to increase the speed and precision of the circuit itself, resulting in a simplified circuit construction.

While the phase shift circuit 203 which shifts the phase of the input signal by 2π is adopted in the phase difference measurement circuit according to the second embodiment, a phase shift circuit which shifts the phase of the input signal by nπ (n: natural number) may be adopted.

### Embodiment 3

A phase difference measurement circuit according to a third embodiment of the present invention measures a phase difference between an input signal having a predetermined period, and a signal that is obtained by delaying the input signal by a predetermined delay amount, in order to perform judgment as to whether a delay circuit is normally operated or not.

Hereinafter, the phase difference measurement circuit according to the third embodiment of the present invention will be described. The same constituents as those of the first embodiment are given the same reference numerals to omit description thereof.

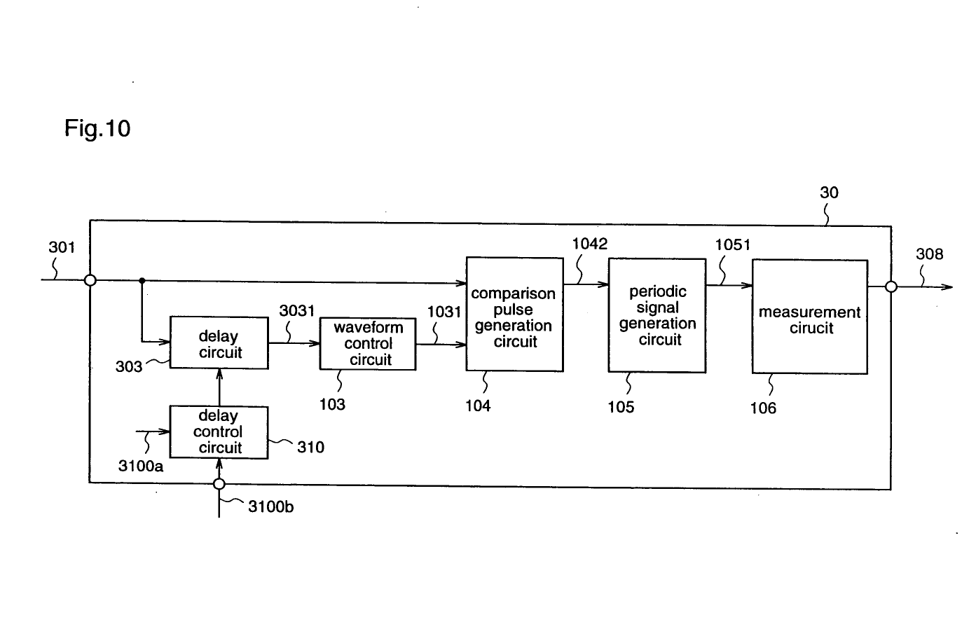

FIG. 10 is a block diagram illustrating the construction of the phase difference measurement circuit 30 according to the third embodiment of the present invention.

In FIG. 10, a delay circuit 303 delays an input signal 301 having a predetermined period by a predetermined delay amount, and a delay control circuit 310 controls the delay amount by which the input signal is delayed in the delay circuit.

Initially, the delay circuit 303 delays the input signal 301 by a predetermined delay amount. For example, assuming that the delay amount is converted to a phase, when the input signal is delayed by a phase θ, the relationship between the output 3031 of the delay circuit 303 and the input signal 301 becomes equivalent to the relationship between the input signal 101 and the input signal 102 which is shown in FIG. 1. Assuming that the waveform control circuit 103 adds 2π to the signal as in the first embodiment, the phase difference between the two signals 301 and 1031 inputted to the comparison pulse generation circuit 104 is 2π+θ. Accordingly, the operation subsequent to the comparison pulse generation circuit 104 is identical to that described for the first embodiment.

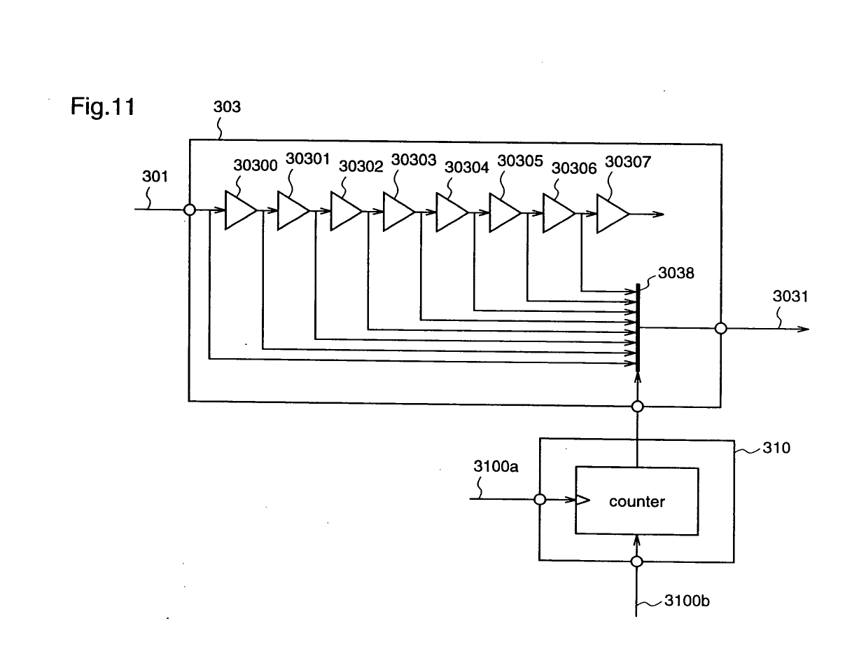

Examples of the delay circuit 303 and the delay control circuit 31 are shown in FIG. 11. The delay circuit 303 comprises buffers 30300 to 30307 as shown in FIG. 11, and every input is inputted to a multiplexer 3038, and only one input is selected by control of the delay control circuit 310 to be an output 3031. The simplest example of the delay control circuit 310 is an up counter. The up counter performs count up with a clock 3100a, and the count value is reset by a reset 3100b. In this third embodiment, the delay circuit 303 is controlled by the delay control circuit 310 so that the delay amount is gradually increased at predetermined time intervals. Although it is not shown in the figure, if the delay amounts of the inputs/outputs of the buffers 30300 to 30307 are controlled with an PLL (Phase Locked Loop) or a DLL (Delay Locked Loop) so as to be equal to the period of the input signal 301, the output 3031 of the delay circuit is phase-shifted by 2πn/8 (n=0˜7) of the input signal 301. Further, while this third embodiment adopts the delay circuit that delays the input signal with the buffers 30300˜30307, the present invention is not restricted thereto, and any delay circuit may be used so long as it can generate two ore more signals having different delay amounts from the input signal.

Hereinafter, a description will be given of the meaning as to why the predetermined delay amount, i.e., the already known phase difference, which is generated in the delay circuit 303 is measured in the subsequent comparison pulse generation circuit 104, periodic signal generation circuit 105, and measurement circuit 106.

When the delay circuit 303 is mounted on a semiconductor, variations in manufacturing are inevitable. Variations in delay time due to electric characteristic and temperature characteristic are also inevitable. Evaluation or examination as to whether the output from the delay circuit 303 is delayed by the set delay amount or not is easily carried out, coupled with these factors. The delay amount, i.e., the phase difference, for each buffer can be selected by the delay control circuit 310, and even when the phase difference is minute, a phase of 2π is added thereto by the waveform control circuit 1103, whereby highly accurate measurement can be carried out. The operation subsequent to the comparison pulse generation circuit 104 is identical to that described for the first embodiment. Thus, whether the input signal is delayed by the normal delay amount for each buffer in the delay circuit 303 can be judged by measuring the phase difference between the input signal 301 and the signal 3031 that is delayed by the delay circuit 303.

The phase difference measurement circuit according to the third embodiment of the present invention is provided with the delay circuit 303 for delaying the input signal 301 by a predetermined delay amount, the delay control circuit 310 for controlling the delay amount of the delay circuit 303, the waveform control circuit 103 for outputting the delayed signal for each predetermined period, the comparison pulse generation circuit 104 for converting the phase difference between the input signal 301 and the signal 1031 that is outputted from the waveform control circuit 103 for each predetermined period, into a pulse width at each predetermined timing, and outputting the converted pulse width 1042, the periodic signal generation circuit 105 for accumulating the phase difference that is converted into the pulse width, and generating a periodic signal 1051 on the basis of the accumulated phase difference, and the measurement circuit 106 for measuring the period of the periodic signal 1051, and the input signal is delayed by a predetermined delay amount by the delay circuit, and a phase difference between the input signal and the signal delayed by the delay circuit is measured. Therefore, whether the input signal is delayed by the set delay amount or not can be confirmed by detecting the phase difference generated by the delay circuit 303, thereby enabling judgment as to whether the delay circuit is normally operated or not.

While in this third embodiment the delay amount is controlled to be gradually increased for each predetermined time interval by using the delay control circuit 310, conversely the delay amount may be controlled to be gradually decreased. Alternatively, it may be changed to a desired delay amount for each predetermined time interval.

While in this third embodiment the delay circuit that can set plural delay amounts is used, a delay circuit having a fixed delay amount may be used. In this case, the delay circuit is reduced in size, and the delay control circuit is not required, leading to a reduction in the circuit scale.

Further, while in the phase difference measurement circuit according to the third embodiment the waveform control circuit generates an output signal so that the phase difference pulse indicating the phase difference between the two input signals is obtained by adding 2π to the original phase difference, the waveform control circuit 103 may generate an output signal so that the phase difference pulse is obtained by adding nπ (n: natural number) to the original phase difference.

### Embodiment 4

A phase difference measurement circuit according to a fourth embodiment of the present invention is provided with a phase shift circuit that shifts an input signal by a predetermined phase, in place of the waveform control circuit of the phase difference measurement circuit according to the third embodiment.

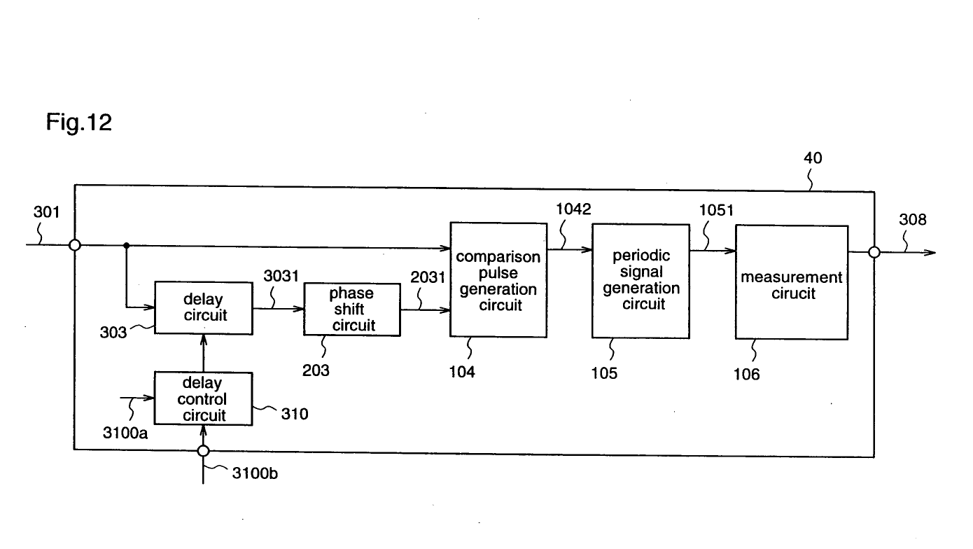

The phase difference measurement circuit 40 according to the fourth embodiment will be described with reference to FIG. 12. The same constituents as those described for the third embodiment are not repeatedly described, and only the constituents different from those of the third embodiment will be described.

FIG. 12 is a diagram illustrating the construction of the phase difference measurement circuit according to the fourth embodiment of the present invention.

With reference to FIG. 12, the phase difference measurement circuit 40 according to the fourth embodiment is provided with a phase shift circuit 203 which shifts the signal 3031 outputted from the delay circuit 303 by a predetermined phase, and outputs the same.

As in the third embodiment, initially, the delay circuit 303 delays the input signal 301 by a predetermined delay amount. For example, assuming that the delay amount is converted to a phase, when the signal is delayed by a phase θ, the relationship between the output 3031 of the delay circuit 303 and the input signal 301 becomes equivalent to the relationship between the input signal 101 and the input signal 102, which is shown in FIG. 1. In the phase shift circuit 203, the input signal is shifted so as to obtain an output signal 2031 having a phase in which each pulse of the input signal is delayed by 2π, as in the second embodiment. Thereby, the phase difference between the two signals 301 and 2031 that are inputted to the comparison pulse generation circuit 104 becomes 2π+θ. Accordingly, the operation subsequent to the comparison pulse generation circuit 104 is identical to that of the first embodiment.

The delay circuit 303 and the delay control circuit 310 are constituted as shown in FIG. 11 as in the third embodiment, and further, the delay circuit 303 is controlled by the delay control circuit 310 so that the delay amount is gradually increased at predetermined time intervals. Further, as in the third embodiment, when the delay amounts of inputs/outputs of the buffers 30300˜30307 are controlled to be equal to the period of the input signal 301 by a PLL (Phase Locked Loop) or a DLL (Delay Locked Loop), the output 3031 of the delay circuit is phase-shifted by 2πn/8 (n: 0˜7) of the input signal 301. Any delay circuit may be adopted so long as it generates two or more signals having different delay amounts from the input signal, on the basis of the control of the delay control circuit.

The phase difference measurement circuit 40 according to the fourth embodiment of the present invention is provided with the delay circuit 303 that delays the input signal 301 by a predetermined delay amount, the delay control circuit 310 that controls the delay amount of the delay circuit 303, the phase shift circuit 203 that shifts, by 2π, the phase 3031 of the signal that is delayed by the delay circuit, the comparison pulse generation circuit 104 that converts the phase difference between the input signal 301 and the signal 2031 that is shifted by 2π by the phase shift circuit into a pulse width at each predetermined timing, and outputs the converted pulse width 1042, the periodic signal generation circuit 105 that accumulates the phase difference converted into the pulse width, and generates a periodic signal 1051 on the basis of the accumulated phase difference, and the measurement circuit 106 that measures the period of the periodic signal 1051, and a phase difference between the input signal having a predetermined period and the signal obtained by delaying the input signal by a predetermined delay amount is measured. Therefore, whether the input signal is delayed by the set delay amount or not can be confirmed by detecting the phase difference that is generated by the delay circuit, thereby enabling judgment as to whether the delay circuit is normally operated or not.

While the phase difference measurement circuit 40 of the fourth embodiment includes the phase shift circuit 203 that shifts the phase of the signal outputted from the delay circuit 303 by 2π, a phase shift circuit that shifts the phase by nπ (n: natural number) may be used.

While in this fourth embodiment the delay amount is controlled to be gradually increased for each predetermined time interval by using the delay control circuit 310, the delay amount may be controlled to be gradually decreased. Alternatively, it may be changed to a desired delay amount for each predetermined time interval.

While in this fourth embodiment the delay circuit that can set plural delay amounts is used, a delay circuit having a fixed delay amount may be used. In this case, the delay circuit can be reduced in size, and the delay control circuit is not required, leading to a reduction in the circuit scale.

### Embodiment 5

In a phase difference measurement circuit according to a fifth embodiment, an inputted signal is delayed by a predetermined amount with a delay circuit, and further, the phase of the delayed signal is delayed by 2π, in place of providing the waveform control circuit of the phase difference measurement circuit in the third embodiment.

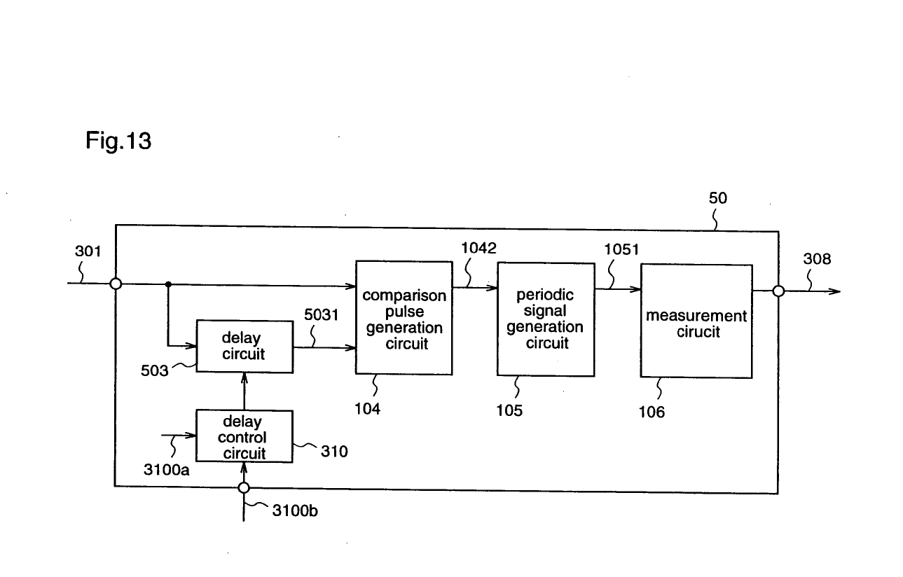

The phase difference measurement circuit 50 according to the fifth embodiment will be described with reference to FIG. 13. The same constituents as those described for the third embodiment are not repeatedly described, and only the constituents different from those of the third embodiment will be described.

FIG. 13 is a diagram illustrating the construction of the phase difference measurement circuit 50 according to the fifth embodiment.

As shown in FIG. 13, the phase difference measurement circuit 50 according to the fifth embodiment is provided with a delay circuit 503 which outputs a signal 5031 that is obtained by delaying the input signal 301 by a predetermined delay amount, and further delaying the phase of the delayed signal by 2π, in place of the waveform control circuit 103 in the third embodiment.

As in the third embodiment, initially, the delay circuit 503 delays the input signal 301 by a predetermined delay amount. Assuming that the delay amount is converted to a phase, the input signal 301 is delayed by θ. Further, the delay circuit 503 obtains an output signal 5031 having a phase in which each pulse of the signal that is delayed by the predetermined delay amount is further delayed by 2π. Thereby, the phase difference between the two signals 301 and 5031 inputted to the comparison pulse generation circuit 104 becomes 2π+θ, and it becomes equivalent to the relationship between the input signals 301 and 1031 which is shown in FIG. 10. Accordingly, the operation subsequent to the comparison pulse generation circuit 104 onward is identical to that of the first embodiment.

In order to shift the phase of the input signal 301 by θ, the delay circuit 503 is provided with buffers 30300˜30307 as shown in FIG. 11, and one of the buffers is selected by the delay control circuit 310. Further, as in the third embodiment, when the delay amounts of the inputs/outputs of the buffers 30300˜30307 are controlled so as to be equal to the period of the input signal 301 by using a PLL (Phase Locked Loop) or a DLL (Delay Locked Loop), the phase is shifted by 2πn/8 (n: 0˜7) of the input signal. The delay circuit 503 is controlled by the delay control circuit so that the delay amount θ is gradually increased at predetermined time intervals. The delay circuit 503 according to the fifth embodiment shifts the phase by 2πn/8 (n: 0˜7) and then further delays the phase by 2π in the subsequent stage. Therefore, when two inverters (not shown) are provided in the stage subsequent to the multiplexer 3038 in addition to the above-mentioned construction, the phase is further delayed by 2π, and the phase of the input signal 301 is shifted by 2π+θ by the delay circuit 503. The phase may be delayed by 2π in the stage before the buffer 30300, and in this case, the inverters are provided in the stage before the buffer 30300.

The phase difference measurement circuit 50 according to the fifth embodiment of the present invention is provided with the delay circuit 503 which delays the input signal by a predetermined delay amount, and further delays the phase of the delayed signal by 2π, the delay control circuit 310 which controls the delay amount of the delay circuit 503, the comparison pulse generation circuit 104 which converts the phase difference between the input signal 301 and the signal 5031 outputted from the delay circuit 503 into a pulse width at each predetermined timing, and outputs the converted pulse width 1042, the periodic signal generation circuit 105 which accumulates the phase difference converted into the pulse width, and generates the periodic signal 1051 on the basis of the accumulated phase difference, and the measurement circuit 106 that measures the period of the periodic signal 1051, and the phase difference between the input signal having a predetermined period and the signal that is obtained by delaying the input signal by the predetermined delay amount is measured. Therefore, whether the input signal is delayed by the set delay amount or not can be confirmed by detecting the phase difference generated by the delay circuit, thereby enabling judgment as to whether the delay circuit is normally operated or not.

While the phase difference measurement circuit according to the fifth embodiment adopts the delay circuit 503 which delays an input signal by a predetermined delay amount and further delays the delayed signal by 2π, a delay circuit which further delays the phase of the delayed signal by nπ (n: natural number) using n pieces of inverters may be adopted.

Further, while in this fifth embodiment the delay amount is controlled to be gradually increased for each predetermined time interval by using the delay control circuit 310, the delay amount may be controlled to be gradually decreased. Further, it may be changed to a desired delay amount for each predetermined time interval.

While in this fifth embodiment the delay circuit that can set plural delay amounts is used, a delay circuit having a fixed delay amount may be used. In this case, the delay circuit can be reduced in size, and the delay control circuit is not required, whereby the circuit scale can be reduced.

### Embodiment 6

A phase difference measurement circuit according to a sixth embodiment of the present invention includes a statistical circuit for obtaining a statistical result for a predetermined period to automatically judge as to whether the delay circuit is normally operated or not, in addition to the phase difference measurement circuit of the third embodiment.

Hereinafter, the phase difference measurement circuit 60 according to the sixth embodiment of the present invention will be described. The same constituents as those described for the first and third embodiments are given the same reference numerals to omit the description thereof.

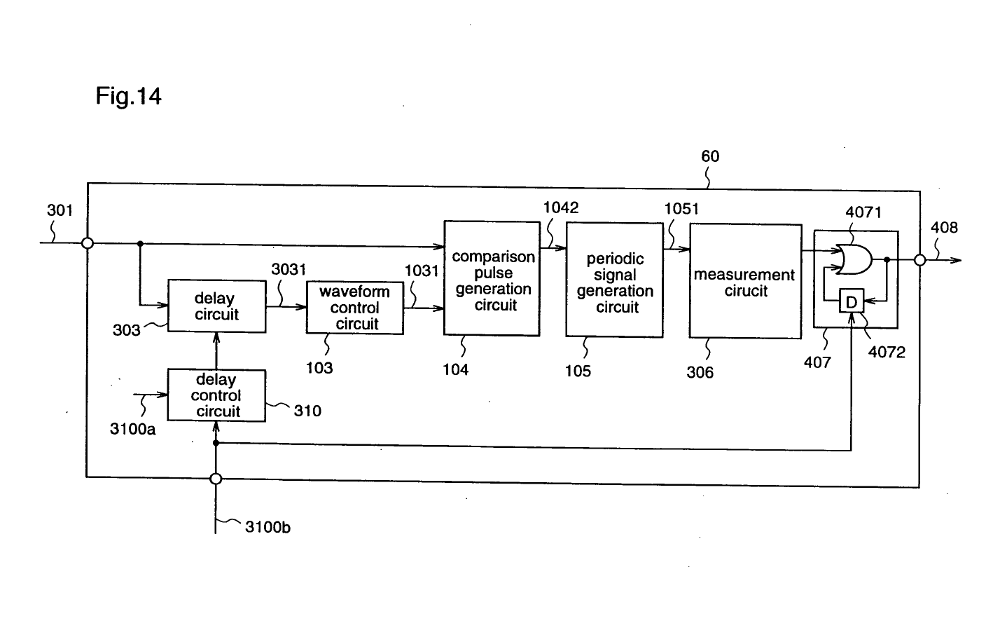

An example of obtaining a statistical result for a predetermined period by using a measurement result will be described with reference to FIGS. 14˜16.

FIG. 14 is a block diagram illustrating the phase difference measurement circuit 60 having the statistical circuit 407 that generates statistical information of the phase difference within a predetermined period, on the basis of the measurement result obtained by the measurement circuit.

As in the third embodiment, initially, the delay circuit 303 delays the input signal 301 by a predetermined delay amount. Assuming that the delay amount is converted to a phase, when the signal is delayed by a phase θ, the relationship between the output 3031 of the delay circuit 303 and the input signal 301 becomes equivalent to the relationship between the input signals 101 and 102, which is shown in FIG. 1. The waveform control circuit 103 adds 2π to the signal as in the first embodiment. Thereby, the phase difference between the two signals 301 and 1031 which are inputted to the comparison pulse generation circuit 104 becomes 2π+θ. Accordingly, the operation subsequent to the comparison pulse generation circuit 104 is identical to that of the first embodiment.

The delay circuit 303 and the delay control circuit 310 are constituted as shown in FIG. 11 as in the third embodiment, and further, the delay circuit 303 is controlled by the delay control circuit 310 so that the delay amount gradually increases at predetermined time intervals. Further, as in the third embodiment, when the delay amounts of the inputs/outputs of the buffers 30300˜30307 are controlled so as to be equal to the period of the input signal 301 by using a PLL (Phase Locked Loop) or a DLL (Delay Locked Loop), the output 3031 of the delay circuit is phase-shifted by 2πn/8 (n: 0˜7) of the input signal. Any delay circuit may be used so long as it can generate two or more signals having different delay amounts from the input signal.

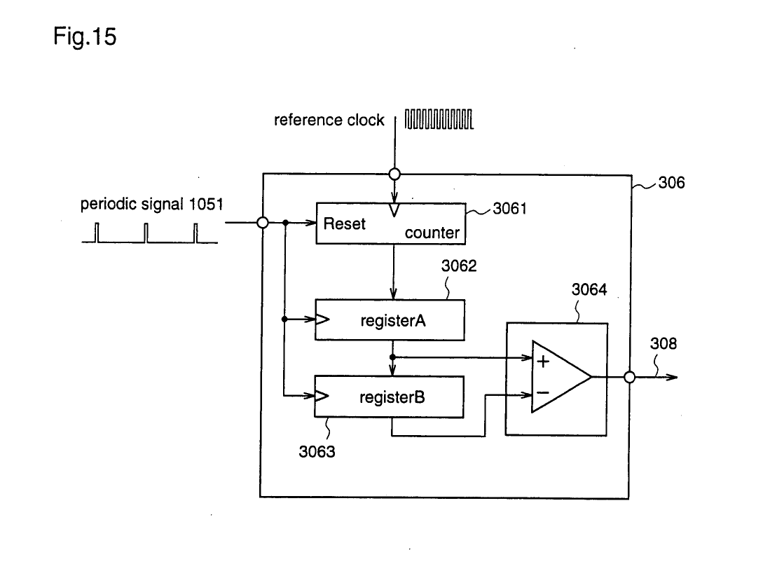

Next, the measurement circuit 306 of the phase difference measurement circuit according to the sixth embodiment will be described with reference to FIG. 15.

FIG. 15 is a diagram illustrating an example of a circuit construction of the measurement circuit 306.

In FIG. 15, the measurement circuit 306 measures the period of the periodic signal 1051 by using a counter 3061. This counter 3061 has a clock for count-up that is a reference clock having an arbitrary frequency (e.g., the same frequency as that of the input signal 301), and a signal for resetting the count value is the periodic signal 1051. A register A 3062 holds the period of the periodic signal, and it holds the count value immediately before the counter 3061 is reset by the periodic signal 1051. A register B 3063 holds the value of the register A 3062 immediately before the register A 3062 is updated by the periodic signal 1051. That is, the period of the immediately previous periodic signal 1051 is held in the register B. A comparator 3064 compares the values of the register A 3062 and the register B 3063, and outputs “1” when the value of the register A 3062 is larger, and outputs “0” when the value of the register B 3063 is larger, as an output 308 of the measurement circuit 306. While in this sixth embodiment two registers are used for holding the measured values in the difference periods, the number of registers is not limited thereto, and more than two registers may be used.

Next, the statistical circuit 407 generates statistical information by saving the history of the output from the measurement circuit 306 within a predetermined period, and it is composed of an OR gate 4071 and a D flip-flop circuit 4072. The D flip-flop circuit 4072 is reset by the same signal as the reset signal 3100b for the delay control circuit 310.

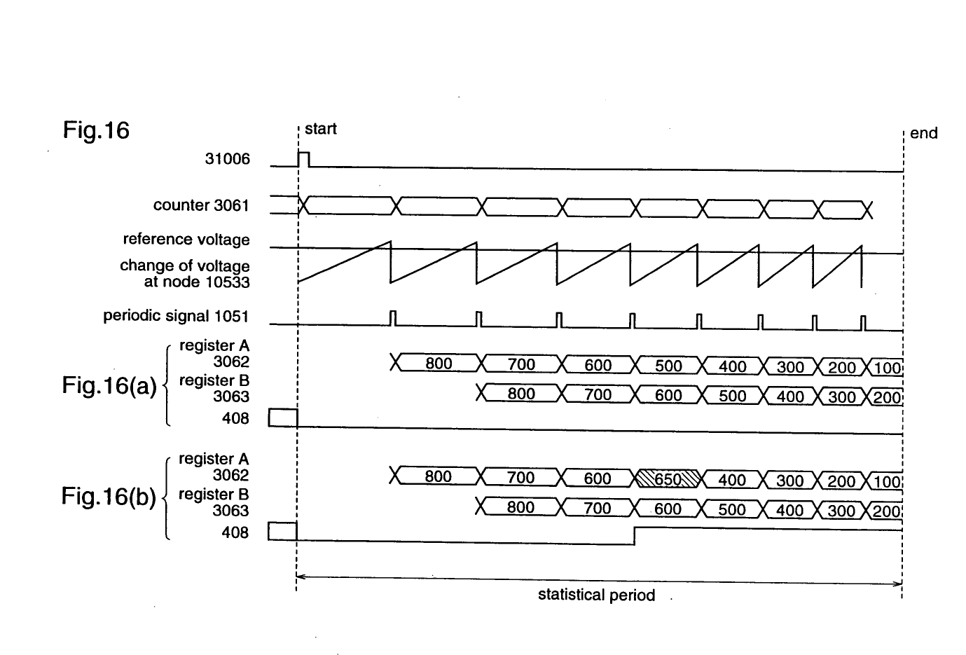

Next, a description will be given of the operation for automatically performing judgment as to whether the delay circuit is normally operated or not, in the phase difference measurement circuit 60 according to the sixth embodiment, with reference to FIG. 16.

For simplification, it is assumed that the delay amount of the delay circuit 303 is measured only one time with respect to a set delay amount, and the delay control circuit 310 is controlled so that the delay amount is monotonously increased. Further, it is assumed that the settling time required until the set delay amount is settled is ignored, and the reference clock of the measurement circuit 306 has the same frequency as that of the input signal 301.

As shown in FIG. 16, although the phase difference obtained by converting the delay amount is initially small, since the delay circuit 303 is controlled by the delay control circuit 310 so that the delay amount is gradually increased, the phase difference is gradually increased. When this effect is indicated by a change in the voltage of the node 10533 of the capacitor 10531, the time required to reach the reference voltage 10541 is gradually shortened. That is, the period of the periodic signal 1051 is shortened, and the numerical value counted by the counter 3061 becomes smaller.

It is found from the above-mentioned processes that, when the delay circuit is controlled by the delay control circuit 310 so that the delay amount is gradually increased, the comparison result between the register A 3062 and the register B 3063, which is inputted to the comparator 3064, indicates that the register B 3063 is always larger than the register A 3062 as shown in FIG. 16(a). Accordingly, the output 308 of the measurement circuit 306 is always 0. If the delay circuit 306 is normally operated independently of variations in manufacturing, temperature characteristics, and electric characteristics, the output 408 of the phase difference measurement circuit 60 is always 0 because the output 308 of the measurement circuit 306 is always 0.

If the magnitude relation becomes abnormal in setting of a delay amount as shown in FIG. 16(b), the output 308 of the comparator 3064 becomes 1, and the abnormal state is kept until the D flip-flop circuit 4072 is reset in the statistical circuit 407. Thereby, evaluation or examination of the required delay amount is continuously carried out, and only presence/absence of occurrence of an abnormal state can be easily measured.

That is, the phase difference measurement circuit 60 constitutes a BIST (Built-In Self Test) circuit that has a measurement start signal 3100b and an evaluation 408 of the measurement result.

While in this sixth embodiment each phase amount is measured by only one time for simplification, it may be measured over plural periods, whereby statistical data such as an average or a variance can be easily obtained.

The phase difference measurement circuit 60 according to the sixth embodiment of the present invention is provided with the delay circuit 303 that delays the input signal 301 by a predetermined delay amount, the delay control circuit 310 that controls the delay amount of the delay circuit 303, the waveform control circuit 103 that outputs the delay signal for each predetermined period, the comparison pulse generation circuit 104 that converts the phase difference between the input signal 301 and the signal 3031 that is outputted from the waveform control circuit for each predetermined period into a pulse width at each predetermined timing, and outputs the converted pulse width 1031, the periodic signal generation circuit 105 that accumulates the phase difference converted into the pulse width, and generates a periodic signal 1051 on the basis of the accumulated phase difference, the measurement circuit 306 that measures the period of the periodic signal 105, and the statistical circuit 407 that generates statistical information of the phase difference within a predetermined period on the basis of the measurement result obtained by the measurement circuit 306, and the phase difference between the input signal 301 having a predetermined period and the signal that is obtained by delaying the input signal 301 by a predetermined delay amount is measured. Therefore, whether the input signal is delayed by the set delay amount or not can be confirmed by detecting the phase difference that is generated by the delay circuit, thereby automatically performing judgment as to whether the delay circuit is normally operated or not.

While in this sixth embodiment the delay amount is controlled to be gradually increased at predetermined time intervals by using the delay control circuit 310, the delay amount may be controlled to be gradually decreased. Alternatively, it may be changed to a desired delay amount for each predetermined time interval.

While in this sixth embodiment the delay circuit that can set plural delay amounts is used, a delay circuit having a fixed delay amount may be used. In this case, the delay circuit can be reduced in size, and the delay control circuit is not required, leading to a reduction in the circuit scale.

Further, while in the phase difference measurement circuit according to the sixth embodiment the waveform control circuit generates an output signal so that the phase difference pulse indicating the phase difference between the two input signals is obtained by adding 2π to the original phase difference, the waveform control circuit 103 may generate an output signal so that the phase difference pulse is obtained by adding nπ (n: natural number) to the original phase difference.

### Embodiment 7

A phase difference measurement circuit according to a seventh embodiment of the present invention is provided with a phase shift circuit that shifts an inputted signal by a predetermined phase, in place of the waveform control circuit of the phase difference measurement circuit in the sixth embodiment.

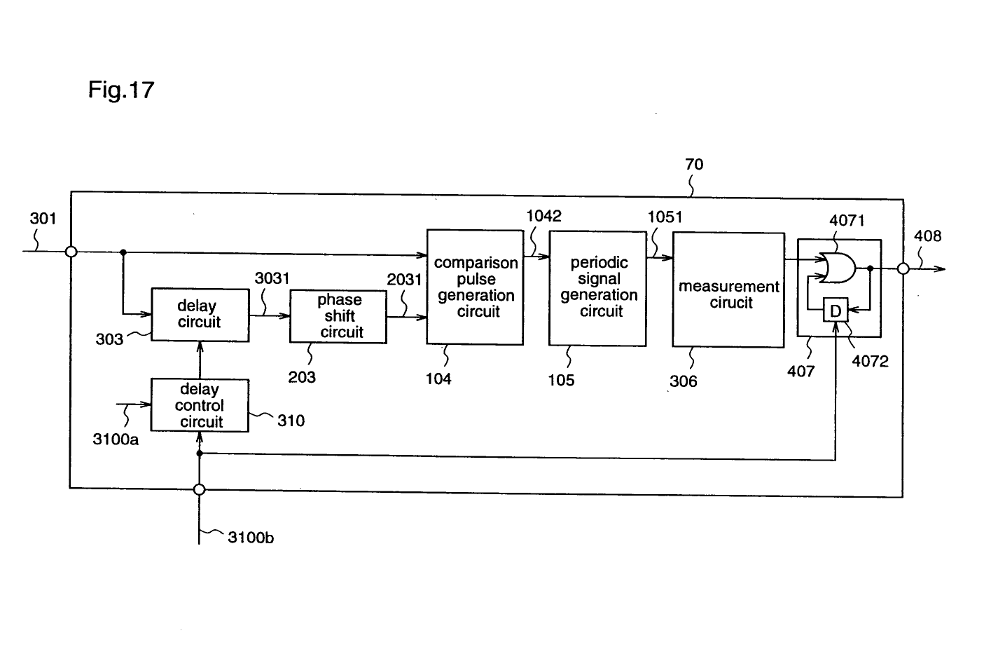

The phase difference measurement circuit according to the seventh embodiment will be described with reference to FIG. 17. The same constituents as those described for the sixth embodiment are not repeatedly described, and only differences from the sixth embodiment will be described.

FIG. 17 is a diagram illustrating the construction of the phase difference measurement circuit according to the seventh embodiment of the present invention.

The phase difference measurement circuit 70 according to the seventh embodiment is provided with the phase shift circuit 203 that shifts the signal 3031 outputted from the delay circuit 303 by a predetermined phase and outputs the same, in place of the waveform control circuit 103 according to the sixth embodiment, as shown in FIG. 17.

As in the sixth embodiment, initially, the delay circuit 303 delays the input signal 301 by a predetermined delay amount. Assuming that the delay amount is converted to a phase, when the signal is delayed by a phase θ, the relationship between the output 3031 of the delay circuit 303 and the input signal 301 becomes equivalent to the relationship between the input signals 101 and 102 shown in FIG. 1. In the phase shift circuit 203, as in the second embodiment, the input signal is shifted so as to obtain an output signal 2031 having a phase in which each pulse of the input signal is delayed by 2π. Thereby, the two input signals 301 and 2031 to be inputted to the comparison pulse generation circuit 104 have a phase difference of 2π+θ, and the relationship between the input signals becomes equivalent to the relationship between the input signal 301 and the output signal 1031 of the waveform control circuit, which is shown in FIG. 14. Accordingly, the operation subsequent to the comparison pulse generation circuit 104 is identical to that of the sixth embodiment.

The delay circuit 303 and the delay control circuit 310 have the constructions as shown in FIG. 11 like the third embodiment, and the delay circuit 303 is controlled by the delay control circuit 310 so that the delay amount is gradually increased at predetermined time intervals. Further, as in the third embodiment, when the delay amounts of the inputs/outputs of the buffers 30300˜30307 are controlled so as to be equal to the period of the input signal 301 by using a PLL (Phase Locked Loop) or a DLL (Delay Locked Loop), the output 3031 of the delay circuit is phase-shifted by 2πn/8 (n=0˜7) of the input signal. Any delay circuit may be used so long as it can generate at least two signals having different delay amounts from the input signal on the basis of the control by the delay control circuit.

The phase difference measurement circuit 70 according to the seventh embodiment of the present invention is provided with the delay circuit 303 that delays the input signal having a predetermined period by a predetermined delay amount, the delay control circuit 310 that controls the delay amount of the delay circuit 303, the phase shift circuit 203 that shifts the phase of the signal delayed by the delay circuit 303 by 2π, the comparison pulse generation circuit 104 that converts the phase difference between the input signal and the signal that is shifted by 2π with the phase shift circuit into a pulse width 1042 at each predetermined timing, and outputs the converted pulse width, the periodic signal generation circuit 306 that accumulates the phase difference converted into the pulse width, and generates a periodic signal 1051 on the basis of the accumulated phase difference, the measurement circuit 306 that measures the period of the periodic signal 1051, and the statistical circuit 407 that generates statistical information of the phase difference within a predetermined period on the basis of the measurement result obtained by the measurement circuit 306, and the phase difference between the input signal having a predetermined period and the signal that is obtained by delaying the input signal by a predetermined delay amount is measured. Therefore, whether the input signal is delayed by the set delay amount or not can be confirmed by detecting the phase difference generated by the delay circuit, thereby automatically performing judgment as to whether the delay circuit is normally operated or not.

While the phase difference measurement circuit according to the seventh embodiment adopts the phase shift circuit 203 that shifts the phase of the signal outputted from the delay circuit 303 by 2π, a phase shift circuit that shifts the signal by nπ (n: natural number) may be adopted.

Further, while in this seventh embodiment the delay amount is controlled to be gradually increased at predetermined time intervals by using the delay control circuit 310, the delay amount may be controlled to be gradually decreased. Alternatively, it may be changed to a desired delay amount for each predetermined time interval.

Furthermore, while in this seventh embodiment the delay circuit that can set plural delay amounts is used, a delay circuit having a fixed delay amount may be used. In this case, the delay circuit can be reduced in size, and the delay control circuit is not required, leading to a reduction in the circuit scale.

### Embodiment 8

A phase difference measurement circuit according to an eighth embodiment of the present invention includes a delay circuit that delays an input signal by a predetermined amount and further delays the phase of the delayed signal by 2π, in place of the waveform control circuit of the phase difference measurement circuit in the sixth embodiment.

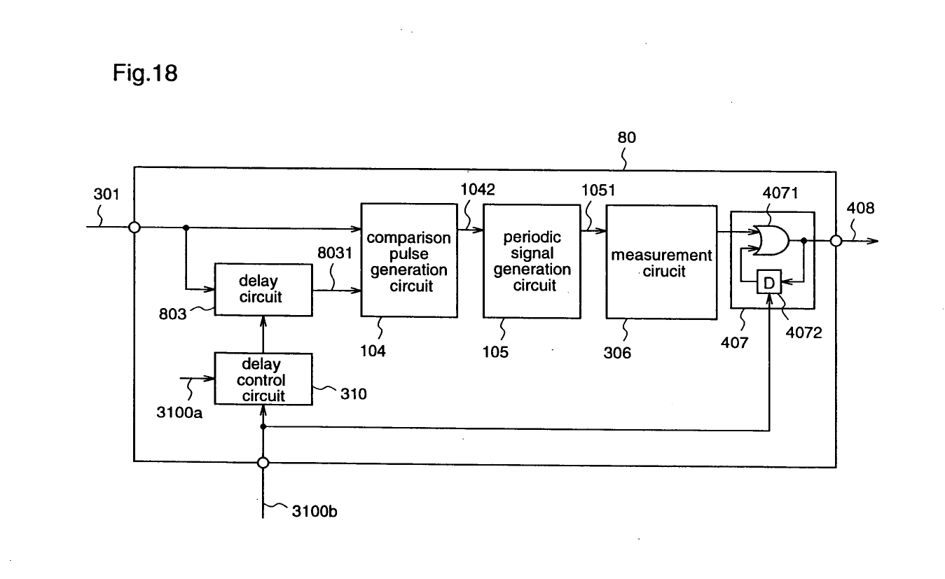

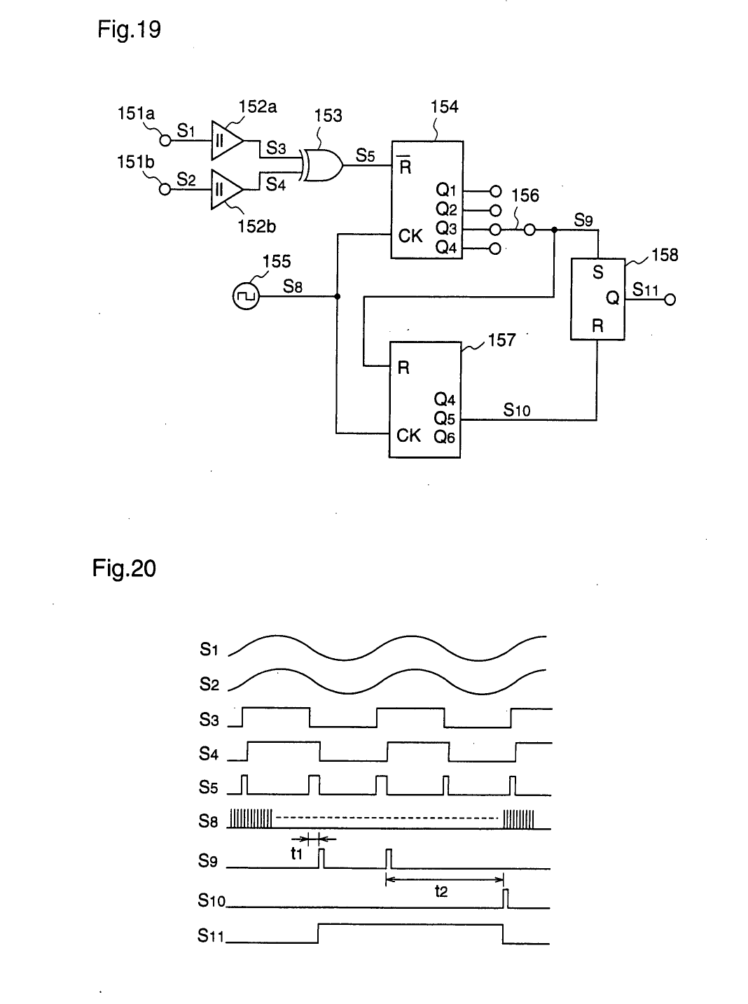

With reference to FIG. 18, the phase difference measurement circuit 80 according to the eighth embodiment will be described. The same constituents as those described for the sixth embodiment are not repeatedly described, and only the constituents different from those of the sixth embodiment will be described.

FIG. 18 is a diagram illustrating the construction of the phase difference measurement circuit 80 according to the eighth embodiment of the present invention.

The phase difference measurement circuit 80 according to the eighth embodiment is provided with a delay circuit 803 that outputs a signal 8031 obtained by delaying the input signal 301 by a predetermined delay amount and further delaying the phase of the delayed signal by 2π, in place of the waveform control circuit 103 in the eighth embodiment.

As in the sixth embodiment, initially, the delay circuit 803 delays the input signal 301 by a predetermined delay amount. Assuming that the delay amount is converted to a phase, the input signal 301 is delayed by θ. Further, the delay circuit 803 obtains an output signal 8031 having a phase in which each pulse of the signal delayed by the predetermined delay amount is further delayed by 2π. Thereby, the phase difference between the two signals 301 and 8031 inputted to the comparison pulse generation circuit 104 becomes 2π+θ, and the relationship between the input signals becomes equivalent to the relationship between the input signal 301 and the output signal of the waveform control circuit 1031, which is shown in FIG. 14. Accordingly, the operation subsequent to the comparison pulse generation circuit 104 is identical to that of the sixth embodiment.

In order to shift the phase of the input signal 301 by θ, the delay circuit 503 is provided with buffers 30300˜30307 as shown in FIG. 11, and one of the buffers is selected by the delay control circuit 310. Further, as in the third embodiment, when the delay amounts of the inputs/outputs of the buffers 30300˜30307 are controlled so as to be equal to the period of the input signal 301 by using a PLL (Phase Locked Loop) or a DLL (Delay Locked Loop), the phase is shifted by 2πn/8 (n: 0˜7) of the input signal. Further, the delay circuit 803 is controlled by the delay control circuit 310 so that the delay amount θ is gradually increased at predetermined time intervals. The delay circuit 803 according to the eighth embodiment shifts the phase by 2πn/8 (n: 0˜7) and then further delays the phase by 2π in the subsequent stage. For example, when two inverters (not shown) are constituted in the stage subsequent to the multiplexer 3038 in addition to the above-mentioned constituents, the phase is further delayed by 2π, whereby the phase of the input signal 301 is shifted by 2π+θ by the delay circuit 803. The phase may be delayed by 2π in the stage before the buffer 30300, and in this case, the inverters are provided in the stage before the buffer 30300.

The phase difference measurement circuit 80 according to the eighth embodiment of the present invention is provided with the delay circuit 803 that delays the input signal having a predetermined period by a predetermined delay amount, and further delays the phase of the delayed signal by 2π, the delay control circuit 310 that controls the delay amount of the delay circuit 803, the comparison pulse generation circuit 104 that converts the phase difference between the input signal 301 and the signal 8031 outputted from the delay circuit 803 into a pulse width 1042 at each predetermined timing, and outputs the converted pulse width, the periodic signal generation circuit 105 that accumulates the phase difference converted into the pulse width, and generates the periodic signal 1051 on the basis of the accumulated phase difference, and the measurement circuit 306 that measures the period of the periodic signal 1051, and the statistical circuit 407 that generates statistical information of the phase difference within a predetermined period on the basis of the measurement result of the measurement circuit 306, and the phase difference between the input signal having a predetermined period and the signal that is obtained by delaying the input signal by a predetermined delay amount is measured. Therefore, whether the input signal is delayed by the set delay amount or not can be confirmed by detecting the phase difference generated by the delay circuit, thereby automatically performing judgment as to whether the delay circuit is normally operated or not.

While the phase difference measurement circuit 80 according to the eighth embodiment adopts the delay circuit 803 that delays an input signal by a predetermined delay amount and further delays the delayed signal by 2π, a delay circuit that further delays the delayed phase by nπ (n: natural number) using n pieces of inverters may be adopted.

Further, while in this eighth embodiment the delay amount is controlled to be gradually increased at predetermined time intervals by using the delay control circuit 310, the delay amount may be controlled to be gradually decreased. Alternatively, it may be changed to a desired delay amount for each predetermined time interval.

While in this eighth embodiment the delay circuit that can set plural delay amounts is used, a delay circuit having a fixed delay amount may be used. In this case, the delay circuit can be reduced in size, and the delay control circuit is not required, leading to a reduction in the circuit scale.

### APPLICABILITY IN INDUSTRY

Since the phase difference measurement circuit according to the present invention can accurately measure a phase difference even when the phase difference is small, it is particularly applicable to a phase difference measurement circuit or the like that needs measurement of a minute phase difference.

1. A phase difference measurement circuit for measuring a phase difference between two input signals, comprising:
a waveform control circuit for outputting one of the two input signals for each predetermined period;
a comparison pulse generation circuit for converting a phase difference between the one input signal that is outputted for each predetermined period from the waveform control circuit and the other input signal, into a pulse width at each predetermined timing, and outputting the converted pulse width;
a periodic signal generation circuit for accumulating the phase difference converted into the pulse width, and generating a periodic signal on the basis of the accumulated phase difference; and
a measurement circuit for measuring the period of the periodic signal.

2. A phase difference measurement circuit for measuring a phase difference between two input signals, comprising:
a phase shift circuit for shifting the phase of one of the two input signals by nπ (n: natural number);
a comparison pulse generation circuit for converting a phase difference between the one input signal that is shifted by nπ by the phase shift circuit and the other input signal, into a pulse width at each predetermined timing, and outputting the converted pulse width;
a periodic signal generation circuit for accumulating the phase difference converted into the pulse width, and generating a periodic signal on the basis of the accumulated phase difference; and
a measurement circuit for measuring the period of the periodic signal.

3. A phase difference measurement circuit as defined in claim 1 wherein said periodic signal generation circuit includes:
a charge pump circuit that is driven by the output of the comparison pulse generation circuit, and outputs electric charge;
a capacitor in which the electric charge outputted from the charge pump circuit is stored; and
a reset pulse generation unit for generating a reset pulse indicating that the voltage stored in the capacitor exceeds an arbitrary reference voltage.

4. A phase difference measurement circuit as defined in claim 3 wherein said charge pump circuit controls the output charge amount according to the pulse width that is outputted from the comparison pulse generation circuit.

5. A phase difference measurement circuit as defined in claim 3 wherein said measurement circuit counts the period of the reset pulse with an arbitrary clock, and converts the period of the reset pulse into a digital numeric value to output the same.

6. A phase difference measurement circuit for measuring a phase difference between an input signal having a predetermined period and a signal that is obtained by delaying the input signal by a predetermined delay amount, comprising:
a delay circuit for delaying the input signal by a predetermined delay amount;
a waveform control circuit for outputting the delayed signal for each predetermined period;
a comparison pulse generation circuit for converting a phase difference between the input signal and the signal that is outputted for each predetermined period from the waveform control circuit, into a pulse width at each predetermined timing, and outputting the converted pulse width;
a periodic signal generation circuit for accumulating the phase difference converted into the pulse width, and generating a periodic signal on the basis of the accumulated phase difference; and
a measurement circuit for measuring the period of the periodic signal.

7. A phase difference measurement circuit for measuring a phase difference between an input signal having a predetermined period and a signal that is obtained by delaying the input signal by a predetermined delay amount, comprising:
a delay circuit for delaying the input signal by a predetermined delay amount;
a phase shift circuit for shifting the phase of the signal that is delayed by the delay circuit, by nπ (n: natural number);
a comparison pulse generation circuit for converting a phase difference between the input signal and the signal that is shifted by nπ by the phase shift circuit, into a pulse width at each predetermined timing, and outputting the converted pulse width;
a periodic signal generation circuit for accumulating the phase difference converted into the pulse width, and generating a periodic signal on the basis of the accumulated phase difference; and
a measurement circuit for measuring the period of the periodic signal.

8. A phase difference measurement circuit for measuring a phase difference between an input signal having a predetermined period and a signal that is obtained by delaying the input signal by a predetermined delay amount, comprising:
a delay circuit for delaying the input signal by a predetermined delay amount, and further delaying the phase of the delayed signal by nπ (n: natural number);
a comparison pulse generation circuit for converting a phase difference between the input signal and the signal that is outputted from the delay circuit, into a pulse width at each predetermined timing, and outputting the converted pulse width;
a periodic signal generation circuit for accumulating the phase difference converted into the pulse width, and generating a periodic signal on the basis of the accumulated phase difference; and
a measurement circuit for measuring the period of the periodic signal.

9. A phase difference measurement circuit as defined in claim 6 further including:
a delay control circuit for controlling the delay amount of the delay circuit; and
said delay circuit generating two or more signals of different delay amounts from the input signal, on the basis of the control of the delay control circuit.

10. A phase difference measurement circuit as defined in claim 9 wherein said delay control circuit changes the delay amount of the delay circuit at predetermined time intervals.

11. A phase difference measurement circuit as defined in claim 9 wherein said delay control circuit performs control to monotonically increase or decrease the delay amount of the delay circuit at predetermined time intervals.

12. A phase difference measurement circuit as defined in claim 6 wherein said periodic signal generation circuit comprises:
a charge pump circuit that is driven according to the output of the comparison pulse generation circuit, and outputs electric charge;
a capacitor in which the electric charge outputted from the charge pump circuit is stored; and
a reset pulse generation unit for generating a reset pulse indicating that the voltage stored in the capacitor exceeds an arbitrary reference voltage.

13. A phase difference measurement circuit as defined in claim 12 wherein said charge pump circuit controls the output charge amount according to the pulse width that is outputted from the comparison pulse generation circuit.

14. A phase difference measurement circuit as defined in claim 12 wherein said measurement circuit counts the period of the reset pulse with an arbitrary clock, and converts the period of the reset pulse into a digital numeric value to output the same.

15. A phase difference measurement circuit for measuring a phase difference between an input signal having a predetermined period and a signal that is obtained by delaying the input signal by a predetermined delay amount, comprising:
a delay circuit for delaying the input signal by a predetermined delay amount;
a waveform control circuit for outputting the delayed signal for each predetermined period;
a comparison pulse generation circuit for converting a phase difference between the input signal and the signal that is outputted for each predetermined period from the waveform control circuit, into a pulse width at each predetermined timing, and outputting the converted pulse width;
a periodic signal generation circuit for accumulating the phase difference converted into the pulse width, and generating a periodic signal on the basis of the accumulated phase difference;
a measurement circuit for measuring the period of the periodic signal; and
a statistical circuit for generating statistical information of the phase difference within a predetermined period on the basis of the measurement result obtained by the measurement circuit.

16. A phase difference measurement circuit for measuring a phase difference between an input signal having a predetermined period and a signal that is obtained by delaying the input signal by a predetermined delay amount, comprising:
a delay circuit for delaying the input signal by a predetermined delay amount;
a phase shift circuit for shifting the phase of the signal that is delayed by the delay circuit, by nπ (n: natural number);
a comparison pulse generation circuit for converting a phase difference between the input signal and the signal that is shifted by nπ by the phase shift circuit, into a pulse width at each predetermined timing, and outputting the converted pulse width;
a periodic signal generation circuit for accumulating the phase difference converted into the pulse width, and generating a periodic signal on the basis of the accumulated phase difference;
a measurement circuit for measuring the period of the periodic signal; and
a statistical circuit for generating statistical information of the phase difference within a predetermined period on the basis of the measurement result obtained by the measurement circuit.

17. A phase difference measurement circuit for measuring a phase difference between an input signal having a predetermined period and a signal that is obtained by delaying the input signal by a predetermined delay amount, comprising:
a delay circuit for delaying the input signal by a predetermined delay amount, and further delaying the phase of the delayed signal by nπ (n: natural number);
a comparison pulse generation circuit for converting a phase difference between the input signal and the signal that is outputted from the delay circuit, into a pulse width at each predetermined timing, and outputting the converted pulse width;
a periodic signal generation circuit for accumulating the phase difference converted into the pulse width, and generating a periodic signal on the basis of the accumulated phase difference;
a measurement circuit for measuring the period of the periodic signal; and
a statistical circuit for generating statistical information of the phase difference within a predetermined period on the basis of the measurement result obtained by the measurement circuit.

18. A phase difference measurement circuit as defined in claim 15 wherein
said measurement circuit includes at least two registers for holding the measurement value, and
said statistical circuit generates statistical information on the basis of the information stored in the registers.

19. A phase difference measurement circuit as defined in claim 15 further including:
a delay control circuit for controlling the delay amount of the delay circuit; and
said delay circuit generating two or more signals of different delay amounts from the input signal on the basis of the control of the delay control circuit.

20. A phase difference measurement circuit as defined in claim 19 wherein said delay control circuit changes the delay amount of the delay circuit at predetermined time intervals.

21. A phase difference measurement circuit as defined in claim 19 wherein
said delay control circuit performs control so as to monolithically increase or decrease the delay amount of the delay circuit at predetermined time intervals.

22. A phase difference measurement circuit as defined in claim 15 wherein said periodic signal generation circuit comprises:
a charge pump circuit that is driven according to the output of the comparison pulse generation circuit, and outputs electric charge;
a capacitor in which the electric charge outputted from the charge pump circuit is stored; and
a reset pulse generation unit for generating a reset pulse indicating that the voltage stored in the capacitor exceeds an arbitrary reference voltage.

23. A phase difference measurement circuit as defined in claim 22 wherein said charge pump circuit controls the output charge amount according to the pulse width that is outputted from the comparison pulse generation circuit.

24. A phase difference measurement circuit as defined in claim 22 wherein said measurement circuit counts the period of the reset pulse with an arbitrary clock, and converts the period of the reset pulse into a digital numeric value to output the same.
